(19) United States
(12) Patent Application Publication
(10) Pub. No.: US 2026/0211069 A1
(43) Pub. Date: Jul. 23, 2026

(54) SYSTEMS AND METHODS FOR GENERATION OF HYPERPOLARIZED MATERIALS

(71) Applicant: NVISION IMAGING TECHNOLOGIES GMBH, Ulm (DE)

(72) Inventors: Ilai SCHWARTZ, Neu-Ulm (DE); Stephan KNECHT, Stuttgart (DE)

(73) Assignee: NVISION IMAGING TECHNOLOGIES GMBH, Ulm (DE)

(21) Appl. No.: 19/138,903

(22) PCT Filed: Dec. 14, 2023
(86) PCT No.: PCT/IB2023/062730

§ 371 Date: Jun. 13, 2025

Related U.S. Application Data
(60) Provisional application No. 63/387,416, filed on Dec. 14, 2022.
(60) Provisional application No. 63/478,437, filed on Jan. 4, 2023.

(51) Int. Cl. G01R 33/56

(52) U.S. Cl. CPC G01R 33/5601

(57) ABSTRACT

Methods for increasing the concentration of a hyperpolarized molecule of interest in solution are disclosed. The hyperpolarized molecule of interest is prepared in an organic solution. A portion of the organic solution is rapidly evaporated to increase its concentration in the solution while maintaining sufficient nuclear spin polarization. The hyperpolarized molecule of interest is then used in an MRI or NMR experiment. Methods for increasing the nuclear spin polarization in molecules of interest polarized by SABRE methods are disclosed. An at least partially deuterated molecule of interest is placed in a magnetic field having a mean magnetic field strength of at most about 2 T. The molecule of interest forms a coordination complex with a SABRE catalyst or pre-catalyst and parahydrogen in solution. An oscillating magnetic field is applied to transfer spin order from the parahydrogen to the molecule of interest, thereby increasing the nuclear spin polarization in the molecule of interest.

### CROSS-REFERENCE

The present application claims priority to U.S. Provisional Patent Application No. 63/387,416, filed on Dec. 14, 2022, and U.S. Provisional Patent Application No. 63/478,437, filed on Jan. 4, 2023, each of which is incorporated herein by reference in its entirety for all purposes.

### TECHNICAL FIELD

The disclosed embodiments generally relate to generation of hyperpolarized materials for use in nuclear magnetic resonance, magnetic resonance imaging, or similar applications.

### BACKGROUND

Nuclear magnetic resonance (NMR) and magnetic resonance imaging (MRI) are technologies with vital applications in chemistry, biology and medical imaging. Despite these successes, it is recognized that nuclear magnetic resonance applications have limitations due to the minute nuclear polarization of analytes (typically on the order of 10⁻⁵). This minute nuclear polarization can result in limited sensitivity in comparison to other analytic techniques such as mass spectrometry.

Increasing nuclear spin polarization beyond its thermal equilibrium value can improve magnetic resonance sensitivity. Nuclear spin polarization can be increased using known techniques like dynamic nuclear polarization (DNP), parahydrogen induced polarization (PHIP), PHIP-sidearm hydrogenation (PHIP-SAH), and signal amplification by reversible exchange (SABRE). Using such techniques, the nuclear spin polarization of a material can be increased 10,000 times or more. The enhanced nuclear spin polarization can result in a proportional increase in the NMR/MRI signal. While this enhanced polarization decays over time due to the relaxation time of the nuclear spins in the polarized molecules, for many molecules the relaxation time can be on the order of seconds to minutes, during which increased polarization can lead to a dramatic increase in NMR/MRI signal sensitivity. By enabling such a dramatic increase in NMR/MRI signal sensitivity, increased nuclear spin polarization can enable new applications, such as the imaging of in vivo metabolism using metabolites with increased nuclear spin polarization in an MRI scanner, accelerate signal NMR spectroscopy investigations, and enable visualization of previously unseen molecular dynamics and structures.

### SUMMARY

The disclosed embodiments include a method for performing a magnetic resonance imaging (MRI) or nuclear magnetic resonance (NMR) procedure using a hyperpolarized molecule of interest. The method can include: (a) obtaining an organic solution having the hyperpolarized molecule of interest dissolved therein at a first concentration; (b) evaporating at least a portion of the organic solution to thereby generate an organic solution having the hyperpolarized molecule of interest dissolved therein at a second concentration greater than the first concentration; and (c) performing the MRI or NMR procedure using the hyperpolarized molecule of interest. The first concentration can be less than 100 millimolar (mM), 90 mM, 80 mM, 70 mM, 60 mM, 50 mM, 40 mM, 30 mM, 20 mM, 10 mM, or less. The second concentration can be at least 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, or more.

The disclosed embodiments include a composition for use in a magnetic resonance imaging (MRI) or nuclear magnetic resonance (NMR) procedure. The composition can comprise: a solution and a hyperpolarized molecule of interest dissolved therein. The composition can be generated by: (a) obtaining an organic solution having the hyperpolarized molecule of interest dissolved therein at a first concentration; and (b) evaporating at least a portion of the organic solution to thereby generate an organic solution having the hyperpolarized molecule of interest dissolved therein at a second concentration greater than the first concentration. The first concentration can be less than 100 millimolar (mM), 90 mM, 80 mM, 70 mM, 60 mM, 50 mM, 40 mM, 30 mM, 20 mM, 10 mM, or less. The second concentration can be at least 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, or more.

The disclosed embodiments include a method for increasing a nuclear spin polarization in a molecule of interest. The method can include: (a) obtaining a molecule of interest comprising at least one deuterium atom; (b) locating the molecule of interest in a magnetic field having a mean magnetic field strength (B₀) of at most about 2 Tesla (T); (c) forming a coordination complex between the molecule of interest, a signal amplification by reversible exchange (SABRE) catalyst or pre-catalyst, and parahydrogen; and (d) applying an oscillating magnetic field to the coordination complex to thereby transfer spin order from the parahydrogen to the molecule of interest and to thereby increase the nuclear spin polarization of at least one atom in the molecule of interest. The oscillating magnetic field can have a maximum field strength of between about 0.1 μT and about 10 millitesla (mT).

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which comprise a part of this specification, illustrate several embodiments and, together with the description, serve to explain the principles and features of the disclosed embodiments. In the drawings:

FIG. 1 depicts an exemplary method for increasing the concentration of a hyperpolarized molecule of interest in solution, in accordance with disclosed embodiments.

FIG. 2 depicts a composition featuring an increased concentration of a hyperpolarized molecule of interest in solution, in accordance with disclosed embodiments.

FIG. 3 depicts an exemplary method for increasing nuclear spin polarization in molecules of interest polarized by SABRE methods, in accordance with disclosed embodiments.

FIG. 4 depicts a composition featuring an increased nuclear spin polarization in a molecule of interest polarized by a SABRE method, in accordance with disclosed embodiments.

FIG. 5 shows exemplary solution concentration increases using manual extraction of solution, in accordance with disclosed embodiments.

FIG. 6 shows exemplary solution concentration increases using automated extraction of solution, in accordance with disclosed embodiments.

FIG. 7 shows exemplary solution concentration increases using automated extraction of solution with deuterium and carbon-labeled DMAD, in accordance with disclosed embodiments.

FIG. 8 shows exemplary ¹³C NMR spectra of [1-¹³C]pyruvate-d₃ and [2-¹³C]pyruvate-d₃ polarized using the SLIC-SABRE methods described herein and the prior gold standard SABRE-SHEATH method, in accordance with disclosed embodiments.

FIG. 9 shows exemplary ¹³C polarization levels for protonated and deuterated [1-¹³C]pyruvate and [2-¹³C]pyruvate polarized using the SLIC-SABRE methods described herein and SABRE-SHEATH, in accordance with disclosed embodiments.

FIG. 10 shows exemplary polarization buildup for protonated and deuterated [1-¹³C]pyruvate and [2-¹³C]pyruvate polarized using the SLIC-SABRE methods described herein and SABRE-SHEATH, in accordance with disclosed embodiments.

FIG. 11 shows exemplary T₁ and T_{1ρ} values for protonated and deuterated [1-¹³C]pyruvate and [2-¹³C]pyruvate, in accordance with disclosed embodiments.

### DETAILED DESCRIPTION

Reference will now be made in detail to exemplary embodiments, discussed with regards to the accompanying drawings. In some instances, the same reference numbers will be used throughout the drawings and the following description to refer to the same or like parts. Unless otherwise defined, technical and/or scientific terms have the meaning commonly understood by one of ordinary skill in the art. The disclosed embodiments are described in sufficient detail to enable those skilled in the art to practice the disclosed embodiments. It is to be understood that other embodiments may be utilized and that changes may be made without departing from the scope of the disclosed embodiments. Thus, the materials, methods, and examples are illustrative only and are not intended to be necessarily limiting.

Nuclear magnetic resonance (NMR) spectroscopy can be used for applications ranging from the determination of chemical structures in synthetic intermediates to the determination of the atomic-level structure and dynamics in proteins and nucleic acids. Magnetic resonance imaging (MRI) can be used for applications such as non-invasive imaging of internal structures (such as tissues or organs) of a biological specimen at sub-millimeter spatial resolution. However, NMR spectroscopy/MRI can have limited sensitivity due to a combination of the minute size of nuclear magnetic moments and the correspondingly small polarization at thermal equilibrium. This limited sensitivity can prevent the use of NMR spectroscopy/MRI in some applications and can render other applications of NMR spectroscopy/MRI impractically time- or material-consuming.

NMR/MRI sensitivity can be increased through the use of higher magnetic fields and optimized detection systems. However, an alternative approach is to increase NMR/MRI sensitivity by increasing nuclear spin polarization to levels significantly greater than thermal equilibrium. Such hyperpolarization techniques can often increase the NMR/MRI sensitivity by a factor that is significantly greater than increasing the magnetic field or using optimized detection systems. Further, such hyperpolarization techniques may enable new NMR spectroscopy/MRI applications, such as observing low-gamma nuclei or low-concentration analytes or molecular imaging.

Nuclear spin polarization can be increased using a variety of techniques, including dynamic nuclear polarization (DNP), parahydrogen-induced polarization (PHIP), PHIP-sidearm hydrolysis (PHIP-SAH), PHIP nuclear Overhauser effect system (PHIPNOESYS), signal amplification by reversible exchange (SABRE), spin-exchange optical pumping (SEOP), optically initialized electron triplet states (also referred to as photoexcited triplet states, PETS), and other suitable methods. Among these techniques, parahydrogen-based methods such as PHIP, PHIP-SAH, PHIPNOESYS, and SABRE are especially promising, as they can be performed at high throughput using relatively low-cost equipment.

For instance, recent work in NMR and MRI has demonstrated that NMR and MRI signals associated with a variety of biorelevant imaging agents can be enhanced by many orders of magnitude using PHIP or PHIP-SAH. Such drastic signal enhancement allows spectroscopic analysis of the biorelevant imaging agent as it is metabolized by various tissues at different locations within a body. Analysis of the metabolic information determined by such spectroscopic imaging may allow non-invasive determination of a health state of tissue within a body. For example, abnormal metabolism of the biorelevant imaging agent may be indicative of a disease such as cancer at some location in the body.

In PHIP and PHIP-SAH, a derivative (e.g., a precursor) of a molecule of interest is reacted with parahydrogen to form a parahydrogenated form of the derivative. Spin order is then transferred from the protons added via the parahydrogenation reaction to a nucleus of interest (such as a carbon-13 nucleus) contained within the molecule of interest. In PHIP, the parahydrogenated form of the derivative is chemically identical to the molecule of interest and distinguished from the molecule of interest only by the spin order derived from the parahydrogenation reaction. In PHIP-SAH, the parahydrogenated form of the derivative is cleaved (e.g., hydrolyzed) to yield the hyperpolarized molecule of interest.

In SABRE, the molecule of interest itself forms a coordination complex with a polarization transfer catalyst or pre-catalyst and parahydrogen. Spin order is then transferred from the parahydrogen to a nucleus of interest within the molecule of interest via the coordination complex. The molecule of interest is then optionally purified and used in an NMR or MRI procedure.

PHIPNOESYS utilizes PHIP or PHIP-SAH to generate a hyperpolarized material (e.g., the source compound) and transfers polarization from the source compound to the material used in NMR spectroscopy (e.g., the target compound). The transfer of polarization from source compound to target compound proceeds via the intermolecular nuclear Overhauser effect (NOE). PHIPNOESYS has been shown to increase signals in NMR spectroscopy by up to a factor of nearly 2,000, allowing for application of NMR spectroscopy at significantly reduced concentrations than would otherwise be achievable.

However, parahydrogen-based methods such as PHIP, PHIP-SAH, PHIPNOESYS, and SABRE may be limited in the concentration of the molecule to which hyperpolarization can be imparted. In some cases, higher concentrations of a hyperpolarized molecule are required, such as when injecting a hyperpolarized molecule into a human subject during a hyperpolarized MRI experiment. For instance, a hyperpolarized MRI molecular imaging experiment may require injection of a hyperpolarized biorelevant imaging agent that has a concentration between about 100 millimolar (mM) and about 200 millimolar (mM). However, PHIP, PHIP-SAH, or SABRE may only be capable of generating the hyperpolarized biorelevant imaging agent at a concentration of, e.g., between about 30 mM and about 50 mM. Accordingly, there is a need for methods and systems that increase the concentration of a hyperpolarized molecule in solution.

Moreover, current SABRE methods may be limited by the relatively short longitudinal (T₁) relaxation times of protons in molecules of interest. Such relatively short relaxation times may limit the polarization that is transferred to the molecule of interest. Accordingly, there is a need for methods and system that increase nuclear spin polarization in molecules of interest polarized by SABRE methods.

The disclosed embodiments increase the concentration of a hyperpolarized molecule of interest in solution. The hyperpolarized molecule of interest is generally prepared in an organic solution at a particular concentration. At least a portion of the organic solution is rapidly evaporated to increase the concentration of the hyperpolarized molecule of interest in the solution while maintaining sufficient nuclear spin polarization to perform the MRI or NMR experiment. The hyperpolarized molecule of interest is then dissolved in aqueous solution to permit the use of the hyperpolarized molecule of interest in the MRI or NMR experiment.

The disclosed embodiments further increase nuclear spin polarization in molecules of interest polarized by SABRE methods. The molecule of interest is at least partially deuterated by replacing at least one proton in the molecule of interest with a deuterium atom. The molecule of interest is placed in a magnetic field having a mean magnetic field strength of at most about 2 tesla (T). The molecule of interest forms a coordination complex with a SABRE catalyst or pre-catalyst and parahydrogen in solution. An oscillating magnetic field is then applied to the coordination complex to transfer spin order from the parahydrogen to the molecule of interest, thereby increasing the nuclear spin polarization in the molecule of interest.

### Hyperpolarization and Parahydrogen

As used in the present disclosure, “polarization” refers to an imbalance in electron or nuclear spins orientations. In some embodiments, polarization can be the normalized, approximate difference in the number of spins in a first direction minus a number of spins in the opposite direction. As a non-limiting example, given 200,000¹H nuclear spins, a polarization of 2% can correspond to 102,000 spins in the first direction and 98,000 in the opposite direction. In some embodiments, “hyperpolarization” can include polarization of a species (e.g., nuclear, election, or the like) in excess of typical polarization levels for that species observed at thermal equilibrium subject to exposure to a specified magnetic field. As a non-limiting example, a sample in a 1 T magnetic field at thermal equilibrium, with ¹H nuclear spin polarization in excess of 0.000341% can be hyperpolarized to have a ¹H nuclear spin polarization substantially higher (e.g., at least one or more orders of magnitude higher) than the 0.000341% thermal equilibrium polarization. As an additional nonlimiting example, a sample in a 3 T magnetic field at thermal equilibrium, with ¹³C spin polarization in excess of 0.000257% can be hyperpolarized. As a further nonlimiting example, a sample in a 3 T magnetic field at thermal equilibrium, with ¹⁵N spin polarization in excess of 0.000103% can be hyperpolarized.

Parahydrogen is a form of molecular hydrogen. In this form of molecular hydrogen, the two proton spins are in the singlet state. In some embodiments, parahydrogen may be formed in a gas form or in a liquid form. For example, in some embodiments, parahydrogen may be generated in gas form by flowing hydrogen gas through a chamber with a catalyst. In some embodiments, the hydrogen gas may be subjected to a low temperature, such as a temperature of at most about 100 K, 90 K, 80 K, 70 K, 60 K, 50 K, 40 K, 30 K, 20 K, 10 K, 9 K, 8 K, 7K, 6 K, 5 K, 4 K, 3 K, or less. In some embodiments, the catalyst may be iron oxide. In some embodiments, the hydrogen gas may contain both parahydrogen and orthohydrogen, and the low temperature can bring the hydrogen gas to thermodynamic equilibrium in the chamber, during which the population of parahydrogen grows.

In some embodiments, the gas can be generated at a first location and subsequently transported to a second location for use. In some embodiments, a first location may be a chamber, which may be part of a container, bottle, holder or other regions capable of holding a gas or a liquid. Such a chamber may be maintained at a suitable pressure, temperature, or combination thereof. In some embodiments, the first location may refer to a physical location such as a room, a lab, a particular warehouse, hospital or other location where the parahydrogen may be generated.

In some embodiments, the generated parahydrogen may be transported in a chamber, which may be different from the chamber where the parahydrogen was generated. The chamber transporting the parahydrogen gas may be maintained at a suitable pressure or temperature and may be transported by vehicle or persons. In some embodiments, transporting the parahydrogen may involve moving the parahydrogen from one container to a different container. In some embodiments, transporting the parahydrogen may involve moving the parahydrogen within the same location, such as from one part of a room to another part of the room. In some embodiments, transporting the parahydrogen may involve moving the parahydrogen from one room in a building to a different room in the same building or to a nearby building. In some embodiments, transporting the parahydrogen may involve moving the parahydrogen to a different location in another part of the same city, or a different city. For example, transporting the parahydrogen may involve bringing the parahydrogen to a vicinity of a polarizer or an NMR/MRI device. In another example, in some embodiments, transporting the parahydrogen may involve packaging or shipping the parahydrogen in suitable containers.

### Methods for Increasing the Concentration of a Hyperpolarized Molecule of Interest in Solution

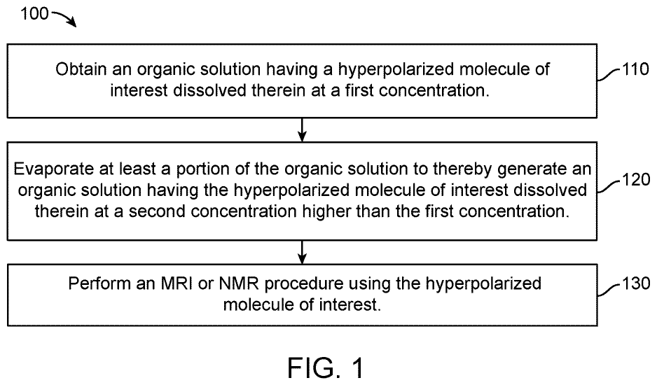

FIG. 1 depicts an exemplary method 100 for increasing the concentration of a hyperpolarized molecule of interest in solution, in accordance with disclosed embodiments. Method 100 utilizes an evaporation procedure to increase the concentration of the hyperpolarized molecule of interest in an organic solution.

At step 110, an organic solution is obtained. In some embodiments, the organic solution contains a hyperpolarized molecule of interest dissolved therein. In some embodiments, the organic solution comprises at least one organic molecule selected from the group consisting of: methanol, ethanol, n-propanol, isopropanol, and acetone. In some embodiments, the hyperpolarized molecule of interest is hyperpolarized via a hyperpolarization procedure such as PHIP, PHIP-SAH, SABRE, PHIPNOESYS, DNP, SEOP, or the like. In some embodiments, the hyperpolarized molecule of interest contains at least one nucleus having a nuclear spin polarization of at least about 1%, 2%, 3%, 4%, 5%, 6%, 7%, 8%, 9%, 10%, 15%, 20%, 25%, 30%, 35%, 40%, 45%, 50%, or more. In some embodiments, the at least one nucleus has a nuclear spin polarization of at most about 50%, 45%, 40%, 35%, 30%, 25%, 20%, 15%, 10%, 9%, 8%, 7%, 6%, 5%, 4%, 3%, 2%, 1%, or less. In some embodiments, the at least one nucleus has a nuclear spin polarization that is within a range defined by any two of the preceding values.

In some embodiments, the hyperpolarized molecule of interest is dissolved in the organic solution at a first concentration. In some embodiments, the first concentration is at most about 100 millimolar (mM), 90 mM, 80 mM, 70 mM, 60 mM, 50 mM, 40 mM, 30 mM, 20 mM, 10 mM, or less. In some embodiments, the first concentration is at least about 10 mM, 20 mM, 30 mM, 40 mM, 50 mM, 60 mM, 70 mM, 80 mM, 90 mM, 100 mM, or more. In some embodiments, the first concentration is within a range defined by any two of the preceding values. For instance, in some embodiments, the first concentration is between about 10 mM and about 100 mM, about 10 mM and about 90 mM, about 10 mM and about 80 mM, about 10 mM and about 70 mM, about 10 mM and about 60 mM, about 10 mM and about 50 mM, about 10 mM and about 40 mM, about 10 mM and about 30 mM, about 10 mM and about 20 mM, about 20 mM and about 100 mM, about 20 mM and about 90 mM, about 20 mM and about 80 mM, about 20 mM and about 70 mM, about 20 mM and about 60 mM, about 20 mM and about 50 mM, about 20 mM and about 30 mM, about 30 mM and about 100 mM, about 30 mM and about 90 mM, about 30 mM and about 80 mM, about 30 mM and about 70 mM, about 30 mM and about 60 mM, about 30 mM and about 50 mM, about 30 mM and about 40 mM, about 40 mM and about 100 mM, about 40 mM and about 90 mM, about 40 mM and about 80 mM, about 40 mM and about 70 mM, about 40 mM and about 60 mM, about 40 mM and about 50 mM, about 50 mM and about 100 mM, about 50 mM and about 90 mM, about 50 mM and about 80 mM, about 50 mM and about 70 mM, about 50 mM and about 60 mM, about 60 mM and about 100 mM, about 60 mM and about 90 mM, about 60 mM and about 80 mM, about 60 mM and about 70 mM, about 70 mM and about 100 mM, about 70 mM and about 90 mM, about 70 mM and about 80 mM, about 80 mM and about 100 mM, about 80 mM and about 90 mM, or about 90 mM and about 100 mM.

At step 120, at least a portion of the organic solution is evaporated. In some embodiments, evaporating the portion of the organic solution increases the concentration of the hyperpolarized compound of interest in the organic solution. That is, in some embodiments, evaporating the portion of the organic solution generates an organic solution having the hyperpolarized molecule of interest dissolved therein at a second concentration. In some embodiments, the second concentration is greater than the first concentration.

In some embodiments, the second concentration exceeds the first concentration by at least about 10%, 20%, 30%, 40%, 50%, 60%, 70%, 80%, 90%, 100%, 125%, 150%, 175%, 200%, 225%, 250%, 275%, 300%, 325%, 350%, 375%, 400%, or more. In some embodiments, the second concentration exceeds the second concentration by at most about 400%, 375%, 350%, 325%, 300%, 275%, 250%, 225%, 200%, 175%, 150%, 125%, 100%, 90%, 80%, 70%, 60%, 50%, 40%, 30%, 20%, 10%, or less. In some embodiments, the second concentration exceeds the first concentration by an amount that is within a range defined by any two of the preceding values. For instance, in some embodiments, the second concentration exceeds the first concentration by between about 10% and about 400%, about 10% and about 350%, about 10% and about 300%, about 10% and about 250%, about 10% and about 200%, about 10% and about 150%, about 10% and about 100%, about 10% and about 90%, about 10% and about 80%, about 10% and about 70%, about 10% and about 60%, about 10% and about 50%, about 10% and about 40%, about 10% and about 30%, about 10% and about 20%, about 20% and about 400%, about 20% and about 350%, about 20% and about 300%, about 20% and about 250%, about 20% and about 200%, about 20% and about 150%, about 20% and about 100%, about 20% and about 90%, about 20% and about 80%, about 20% and about 70%, about 20% and about 60%, about 20% and about 50%, about 20% and about 40%, about 20% and about 30%, about 30% and about 400%, about 30% and about 350%, about 30% and about 300%, about 30% and about 250%, about 30% and about 200%, about 30% and about 150%, about 30% and about 100%, about 30% and about 90%, about 30% and about 80%, about 30% and about 70%, about 30% and about 60%, about 30% and about 50%, about 30% and about 40%, about 40% and about 400%, about 40% and about 350%, about 40% and about 300%, about 40% and about 250%, about 40% and about 200%, about 40% and about 150%, about 40% and about 100%, about 40% and about 90%, about 40% and about 80%, about 40% and about 70%, about 40% and about 60%, about 40% and about 50%, about 50% and about 400%, about 50% and about 350%, about 50% and about 300%, about 50% and about 250%, about 50% and about 200%, about 50% and about 150%, about 50% and about 100%, about 50% and about 90%, about 50% and about 80%, about 50% and about 70%, about 50% and about 60%, about 60% and about 400%, about 60% and about 350%, about 60% and about 300%, about 60% and about 250%, about 60% and about 200%, about 60% and about 150%, about 60% and about 100%, about 60% and about 90%, about 60% and about 80%, about 60% and about 70%, about 70% and about 400%, about 70% and about 350%, about 70% and about 300%, about 70% and about 250%, about 70% and about 200%, about 70% and about 150%, about 70% and about 100%, about 70% and about 90%, about 70% and about 80%, about 80% and about 400%, about 80% and about 350%, about 80% and about 300%, about 80% and about 250%, about 80% and about 200%, about 80% and about 150%, about 80% and about 100%, about 80% and about 90%, about 90% and about 400%, about 90% and about 350%, about 90% and about 300%, about 90% and about 250%, about 90% and about 200%, about 90% and about 150%, about 90% and about 100%, about 100% and about 400%, about 100% and about 350%, about 100% and about 300%, about 100% and about 250%, about 100% and about 200%, about 100% and about 150%, about 150% and about 400%, about 150% and about 350%, about 150% and about 300%, about 150% and about 250%, about 150% and about 200%, about 200% and about 400%, about 200% and about 350%, about 200% and about 300%, about 200% and about 250%, about 250% and about 400%, about 250% and about 350%, about 250% and about 300%, about 300% and about 400%, about 300% and about 350%, or about 350% and about 400%.

In some embodiments, the second concentration is at least about 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, 225 mM, 250 mM, 275 mM, 300 mM, 325 mM, 350 mM, 375 mM, 400 mM, 425 mM, 450 mM, 475 mM, 500 mM, or more. In some embodiments, the second concentration is at most about 500 mM, 475 mM, 450 mM, 425 mM, 400 mM, 375 mM, 350 mM, 325 mM, 300 mM, 275 mM, 250 mM, 225 mM, 200 mM, 190 mM, 180 mM, 170 mM, 160 mM, 150 mM, 140 mM, 130 mM, 120 mM, 110 mM, 100 mM, 90 mM, 80 mM, 70 mM, 60 mM, 50 mM, or less. In some embodiments, the second concentration is within a range defined by any two of the preceding values. For instance, in some embodiments, the second concentration is between about 50 mM and about 500 mM, about 50 mM and about 450 mM, about 50 mM and about 400 mM, about 50 mM and about 350 mM, about 50 mM and about 300 mM, about 50 mM and about 250 mM, about 50 mM and about 200 mM, about 50 mM and about 150 mM, about 50 mM and about 100 mM, about 50 mM and about 90 mM, about 50 mM and about 80 mM, about 50 mM and about 70 mM, about 50 mM and about 60 mM, about 60 mM and about 500 mM, about 60 mM and about 450 mM, about 60 mM and about 400 mM, about 60 mM and about 350 mM, about 60 mM and about 300 mM, about 60 mM and about 250 mM, about 60 mM and about 200 mM, about 60 mM and about 150 mM, about 60 mM and about 100 mM, about 60 mM and about 90 mM, about 60 mM and about 80 mM, about 60 mM and about 70 mM, about 70 mM and about 500 mM, about 70 mM and about 450 mM, about 70 mM and about 400 mM, about 70 mM and about 350 mM, about 70 mM and about 300 mM, about 70 mM and about 250 mM, about 70 mM and about 200 mM, about 70 mM and about 150 mM, about 70 mM and about 100 mM, about 70 mM and about 90 mM, about 70 mM and about 80 mM, about 80 mM and about 500 mM, about 80 mM and about 450 mM, about 80 mM and about 400 mM, about 80 mM and about 350 mM, about 80 mM and about 300 mM, about 80 mM and about 250 mM, about 80 mM and about 200 mM, about 80 mM and about 150 mM, about 80 mM and about 100 mM, about 80 mM and about 90 mM, about 90 mM and about 500 mM, about 90 mM and about 450 mM, about 90 mM and about 400 mM, about 90 mM and about 350 mM, about 90 mM and about 300 mM, about 90 mM and about 250 mM, about 90 mM and about 200 mM, about 90 mM and about 150 mM, about 90 mM and about 100 mM, about 100 mM and about 500 mM, about 100 mM and about 450 mM, about 100 mM and about 400 mM, about 100 mM and about 350 mM, about 100 mM and about 300 mM, about 100 mM and about 250 mM, about 100 mM and about 200 mM, about 100 mM and about 150 mM, about 150 mM and about 500 mM, about 150 mM and about 450 mM, about 150 mM and about 400 mM, about 150 mM and about 350 mM, about 150 mM and about 300 mM, about 150 mM and about 250 mM, about 150 mM and about 200 mM, about 200 mM and about 500 mM, about 200 mM and about 450 mM, about 200 mM and about 400 mM, about 200 mM and about 350 mM, about 200 mM and about 300 mM, about 200 mM and about 250 mM, about 250 mM and about 500 mM, about 250 mM and about 450 mM, about 250 mM and about 400 mM, about 250 mM and about 350 mM, about 250 mM and about 300 mM, about 300 mM and about 500 mM, about 300 mM and about 450 mM, about 300 mM and about 400 mM, about 300 mM and about 350 mM, about 350 mM and about 500 mM, about 350 mM and about 450 mM, about 350 mM and about 400 mM, about 400 mM and about 500 mM, about 400 mM and about 450 mM, or about 450 mM and about 500 mM.

In some embodiments, evaporating the portion of the organic solution comprises performing at least one evaporation procedure. In some embodiments, the at least one evaporation procedure is selected from the group consisting of: flowing an inert gas (e.g., nitrogen or argon gas) across the organic solution, subjecting the organic solution to vacuum, and heating the organic solution. In some embodiments, the organic solution is heated to a temperature of at least about 30 degrees Celsius (° C.), 40° C., 50° C., 60 ° C., 70° C., 80° C., 90° C., 100° C., or more. In some embodiments, the organic solution is heated to a temperature of at most about 100 ° C., 90° C., 80° C., 70° C., 60° C., 50° C., 40° C., 30° C., or less. In some embodiments, the organic solution is heated to a temperature that is within a range defined by any two of the preceding values. In some embodiments, the at least one evaporation procedure comprises at least about 1, 2, 3, 4, 5, 6, 7, 8, 9, 10, or more evaporation procedures. In some embodiments, the at least one evaporation procedure comprises at most about 10, 9, 8, 7, 6, 5, 4, 3, 2, or 1 evaporation procedures. In some embodiments, the at least one evaporation procedure comprises a number of evaporation procedures that is within a range defined by any two of the preceding values. For instance, in some embodiments, between about 1 and about 10, about 1 and about 9, about 1 and about 8, about 1 and about 7, about 1 and about 6, about 1 and about 5, about 1 and about 4, about 1 and about 3, about 1 and about 2, about 2 and about 10, about 2 and about 9, about 2 and about 8, about 2 and about 7, about 2 and about 6, about 2 and about 5, about 2 and about 4, about 2 and about 3, about 3 and about 10, about 3 and about 9, about 3 and about 8, about 3 and about 7, about 3 and about 6, about 3 and about 5, about 3 and about 4, about 4 and about 10, about 4 and about 9, about 4 and about 8, about 4 and about 7, about 4 and about 6, about 4 and about 5, about 5 and about 10, about 5 and about 9, about 5 and about 8, about 5 and about 7, about 5 and about 6, about 6 and about 10, about 6 and about 9, about 6 and about 8, about 6 and about 7, about 7 and about 10, about 7 and about 9, about 7 and about 8, about 8 and about 10, about 8 and about 9, or about 9 and about 10 evaporation procedures are performed.

At step 130, an NMR or MRI procedure is performed using the hyperpolarized molecule of interest. In some embodiments, the NMR or MRI procedure is performed using the organic solution. In some embodiments, the NMR or MRI procedure is performed using a different organic solution into which the hyperpolarized molecule of interest has been dissolved (e.g., via a precipitation and redissolution procedure or a solvent exchange procedure). In some embodiments, the NMR or MRI procedure is performed using an aqueous solution into which the hyperpolarized molecule of interest has been dissolved (e.g., via a precipitation and redissolution procedure or a solvent exchange procedure). Examples of precipitation and redissolution procedures are provided in WO2022018514 and WO2022269350, each of which is incorporated herein by reference in its entirety for all purposes. Examples of solvent exchange procedures are provided in WO2022269350, which is incorporated herein by reference in its entirety for all purposes.

For instance, in some embodiments, prior to step 130, the organic solution is mixed with water or a different organic solvent to thereby generate an aqueous or organic solution having the hyperpolarized compound dissolved therein at a third concentration. In some embodiments, the third concentration is at least about 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, 225 mM, 250 mM, 275 mM, 300 mM, 325 mM, 350 mM, 375 mM, 400 mM, 425 mM, 450 mM, 475 mM, 500 mM, or more. In some embodiments, the third concentration is at most about 500 mM, 475 mM, 450 mM, 425 mM, 400 mM, 375 mM, 350 mM, 325 mM, 300 mM, 275 mM, 250 mM, 225 mM, 200 mM, 190 mM, 180 mM, 170 mM, 160 mM, 150 mM, 140 mM, 130 mM, 120 mM, 110 mM, 100 mM, 90 mM, 80 mM, 70 mM, 60 mM, 50 mM, or less. In some embodiments, the third concentration is within a range defined by any two of the preceding values. For instance, in some embodiments, the third concentration is between about 50 mM and about 500 mM, about 50 mM and about 450 mM, about 50 mM and about 400 mM, about 50 mM and about 350 mM, about 50 mM and about 300 mM, about 50 mM and about 250 mM, about 50 mM and about 200 mM, about 50 mM and about 150 mM, about 50 mM and about 100 mM, about 50 mM and about 90 mM, about 50 mM and about 80 mM, about 50 mM and about 70 mM, about 50 mM and about 60 mM, about 60 mM and about 500 mM, about 60 mM and about 450 mM, about 60 mM and about 400 mM, about 60 mM and about 350 mM, about 60 mM and about 300 mM, about 60 mM and about 250 mM, about 60 mM and about 200 mM, about 60 mM and about 150 mM, about 60 mM and about 100 mM, about 60 mM and about 90 mM, about 60 mM and about 80 mM, about 60 mM and about 70 mM, about 70 mM and about 500 mM, about 70 mM and about 450 mM, about 70 mM and about 400 mM, about 70 mM and about 350 mM, about 70 mM and about 300 mM, about 70 mM and about 250 mM, about 70 mM and about 200 mM, about 70 mM and about 150 mM, about 70 mM and about 100 mM, about 70 mM and about 90 mM, about 70 mM and about 80 mM, about 80 mM and about 500 mM, about 80 mM and about 450 mM, about 80 mM and about 400 mM, about 80 mM and about 350 mM, about 80 mM and about 300 mM, about 80 mM and about 250 mM, about 80 mM and about 200 mM, about 80 mM and about 150 mM, about 80 mM and about 100 mM, about 80 mM and about 90 mM, about 90 mM and about 500 mM, about 90 mM and about 450 mM, about 90 mM and about 400 mM, about 90 mM and about 350 mM, about 90 mM and about 300 mM, about 90 mM and about 250 mM, about 90 mM and about 200 mM, about 90 mM and about 150 mM, about 90 mM and about 100 mM, about 100 mM and about 500 mM, about 100 mM and about 450 mM, about 100 mM and about 400 mM, about 100 mM and about 350 mM, about 100 mM and about 300 mM, about 100 mM and about 250 mM, about 100 mM and about 200 mM, about 100 mM and about 150 mM, about 150 mM and about 500 mM, about 150 mM and about 450 mM, about 150 mM and about 400 mM, about 150 mM and about 350 mM, about 150 mM and about 300 mM, about 150 mM and about 250 mM, about 150 mM and about 200 mM, about 200 mM and about 500 mM, about 200 mM and about 450 mM, about 200 mM and about 400 mM, about 200 mM and about 350 mM, about 200 mM and about 300 mM, about 200 mM and about 250 mM, about 250 mM and about 500 mM, about 250 mM and about 450 mM, about 250 mM and about 400 mM, about 250 mM and about 350 mM, about 250 mM and about 300 mM, about 300 mM and about 500 mM, about 300 mM and about 450 mM, about 300 mM and about 400 mM, about 300 mM and about 350 mM, about 350 mM and about 500 mM, about 350 mM and about 450 mM, about 350 mM and about 400 mM, about 400 mM and about 500 mM, about 400 mM and about 450 mM, or about 450 mM and about 500 mM.

In some embodiments, the method 100 is performed rapidly. In some embodiments, rapid performance of the method 100 enables the concentration of the molecule of interest to be increased while preventing significant loss of nuclear spin polarization in the molecule of interest. In some embodiments, the method 100 (or one, two, or three of steps 110, 120, and 130) is performed within a total period of at most about 180 seconds(s), 170 s, 160 s, 150 s, 140 s, 130 s, 120 s, 110 s, 100 s, 90 s, 80 s, 70 s, 60 s, 50 s, 40 s, 30 s, 20 s, 19 s, 18 s, 17 s, 16 s, 15 s, 14 s, 13 s, 12 s, 11 s, 10 s, 9 s, 8 s, 7 s, 6 s, 5 s, 4 s, 3 s, 2 s, 1 s, or less. In some embodiments, the method 100 (or one, two, or three of steps 110, 120, and 130) is performed within a period of at least about 1 s, 2 s, 3 s, 4 s, 5 s, 6 s, 7 s, 8 s, 9 s, 10 s, 11 s, 12 s, 13 s, 14 s, 15 s, 16 s, 17 s, 18 s, 19 s, 20 s, 30 s, 40 s, 50 s, 60 s, 70 s, 80 s, 90 s, 100 s, 110 s, 120 s, 130 s, 140 s, 150 s, 160 s, 170 s, 180 s, or more. In some embodiments, the method 100 (or one, two, or three of steps 110, 120, and 130) is performed within a period that is within a range defined by any two of the preceding values.

In some embodiments, rapid performance of the method 100 results in a relatively low loss of nuclear spin polarization in the molecule of interest. For instance, in some embodiments, immediately following step 110, at least one nucleus of the hyperpolarized molecule of interest has a first nuclear spin polarization. In some embodiments, prior to step 130, the at least one nucleus of the hyperpolarized molecule of interest has a second nuclear spin polarization. In some embodiments, the second nuclear spin polarization is reduced from the first nuclear spin polarization by no more than 5%, 10%, 15%, 20%, 25%, 30%, 35%, 40%, 45%, or 50%. That is, in some embodiments, the second nuclear spin polarization is no less than 95%, 90%, 85%, 80%, 75%, 70%, 65%, 60%, 55%, or 50% of the first nuclear spin polarization. In some embodiments, the second nuclear spin polarization is reduced from the first nuclear spin polarization by no less than 50%, 45%, 40%, 35%, 30%, 25%, 20%, 15%, 10%, or 5%. That is, in some embodiments, the second nuclear spin polarization is no more than 50%, 55%, 60%, 65%, 70%, 75%, 80%, 85%, 90%, or 95% of the first nuclear spin polarization. In some embodiments, the second nuclear spin polarization is reduced from the first nuclear spin polarization by an amount that is within a range defined by any two of the preceding values. For instance, in some embodiments, the second nuclear spin polarization is about 50% to about 95%, about 50% to about 90%, about 50% to about 85%, about 50% to about 80%, about 50% to about 75%, about 50% to about 70%, about 50% to about 65%, about 50% to about 60%, about 50% to about 55%, about 55% to about 95%, about 55% to about 90%, about 55% to about 85%, about 55% to about 80%, about 55% to about 75%, about 55% to about 70%, about 55% to about 65%, about 55% to about 60%, about 60% to about 95%, about 60% to about 90%, about 60% to about 85%, about 60% to about 80%, about 60% to about 75%, about 60% to about 70%, about 60% to about 65%, about 65% to about 95%, about 65% to about 90%, about 65% to about 85%, about 65% to about 80%, about 65% to about 75%, about 65% to about 70%, about 70% to about 95%, about 70% to about 90%, about 70% to about 85%, about 70% to about 80%, about 70% to about 75%, about 75% to about 95%, about 75% to about 90%, about 75% to about 85%, about 75% to about 80%, about 80% to about 95%, about 80% to about 90%, about 80% to about 85%, about 85% to about 95%, about 85% to about 90%, or about 90% to about 95% of the first nuclear spin polarization.

In some embodiments, the method 100 comprises generating the hyperpolarized molecule of interest. In some embodiments, the hyperpolarized molecule of interest is generated prior to step 110. In some embodiments, the hyperpolarized molecule of interest is generated using at least one hyperpolarization procedure selected from the group consisting of: PHIP, PHIP-SAH, PHIPNOESYS, and SABRE. For instance, in some embodiments, the hyperpolarized molecule of interest is generated using the methods described in any of WO2022157534, WO2022018514, WO2021198776, WO2022269350, U.S. Pat. No. 8,154,284, WO2022162466, and PCT/IB2023/059050, each of which is incorporated herein by reference in its entirety for all purposes.

In some embodiments, the hyperpolarized molecule of interest comprises any hyperpolarized biorelevant imaging agent describe herein. In some embodiments, the hyperpolarized molecule of interest is selected from the group consisting of: dimethyl maleate, pyruvate, glutamate, glutamine, lactate, acetate, acetoacetate, zymonate, alanine, fructose, fumarate, bicarbonate, urea, dehydroascorbate, alpha ketoglutarate, dihydroxyacetone, glucose, ascorbate, and conjugate acids thereof.

### Compositions Featuring an Increased Concentration of a Hyperpolarized Molecule of Interest in Solution

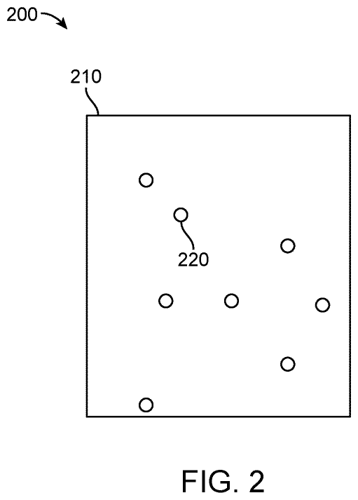

FIG. 2 depicts a composition 200 featuring an increased concentration of a hyperpolarized molecule of interest in solution, in accordance with disclosed embodiments. In the example shown, the composition 200 comprises a solution 210 and a hyperpolarized molecule of interest 220. In some embodiments, the solution 210 comprises any solution described herein with respect to FIG. 1. In some embodiments, the hyperpolarized molecule of interest 220 comprises any hyperpolarized molecule of interest described herein with respect to FIG. 1. In some embodiments, the solution is for use in any NMR or MRI procedure described herein with respect to FIG. 1, such as any PHIP, PHIP-SAH, PHIPNOESYS, or SABRE procedure described herein with respect to FIG. 1.

In some embodiments, the composition 200 is generated using the method 100 described herein with respect to FIG. 1. That is, in some embodiments, the composition 200 is generated by: (a) obtaining an organic solution having the hyperpolarized molecule of interest dissolved therein at a first concentration; and (b) evaporating at least a portion of the organic solution to thereby generate an organic solution having the hyperpolarized molecule of interest dissolved therein at a second concentration greater than the first concentration. In some embodiments, the organic solution comprises any organic solution described herein with respect to FIG. 1. In some embodiments, the first concentration comprises any first concentration described herein with respect to FIG. 1. In some embodiments, the second concentration comprises any second concentration described herein with respect to FIG. 1. In some embodiments, (b) comprises evaporating at least the portion by performing any evaporation procedure described herein with respect to FIG. 1. In some embodiments, (a) and (b) are performed for any total period described herein with respect to FIG. 1. In some embodiments, immediately following (a), at least one nucleus of the hyperpolarized molecule of interest has any first nuclear spin polarization described herein with respect to FIG. 1. In some embodiments, immediately prior to use of the composition in the MRI or NMR procedure, the at least one nucleus of the hyperpolarized molecule of interest has any second nuclear spin described herein with respect to FIG. 1. In some embodiments, the composition is further generated by, prior to (a) generating the hyperpolarized molecule of interest using at least one hyperpolarization procedure described herein with respect to FIG. 1. In some embodiments, the composition is further generated by, subsequent to (b), mixing the organic solution with water to thereby generate an aqueous solution having the hyperpolarized compound dissolved therein at any third concentration described herein with respect to FIG. 1. In some embodiments, the aqueous solution is used in the NMR or MRI procedure.

### Methods for Increasing Nuclear Spin Polarization in Molecules of Interest Polarized by SABRE Methods

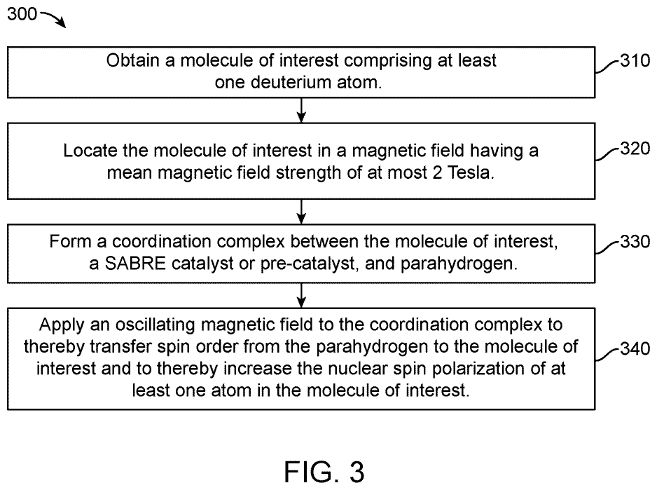

FIG. 3 depicts an exemplary method 300 for increasing nuclear spin polarization in molecules of interest polarized by SABRE methods, in accordance with disclosed embodiments. Method 300 utilizes partial or complete deuteration of the molecule of interest and/or placing the molecule of interest in relatively low magnetic field during a SABRE polarization procedure.

At step 310, a molecule of interest is obtained. In some embodiments, the molecule of interest is to be polarized via a SABRE polarization procedure. In some embodiments, the molecule of interest is dissolved in a solution. In some embodiments, the solution comprises an organic solution. In some embodiments, the organic solution comprises methanol, ethanol, a methanol-water mixture, an ethanol-water mixture, pyridine, chloroform, dichloromethane, acetone, dimethylsulfoxide (DMSO), a sulfur-containing molecule, or any mixture thereof. In some embodiments, the molecule of interest comprises at least one carbon-13 (¹³C) or nitrogen-15 (¹⁵N) atom.

In some embodiments, the molecule of interest comprises a deuterium (²H) enriched molecule of interest. That is, in some embodiments, the molecule of interest comprises at least one deuterium atom at a chemical site on the molecule of interest where a proton (H) would typically be expected. In some embodiments, the molecule of interest comprises at least about 1, 2, 3, 4, 5, 6, 7, 8, 9, 10, 11, 12, 13, 14, 15, 16, 17, 18, 19, 20, or more deuterium atoms at chemical sites on the molecule of interest where protons would typically be expected. In some embodiments, the molecule of interest comprises at most about 20, 19, 18, 17, 16, 15, 14, 13, 12, 11, 10, 9, 8, 7, 6, 5, 4, 3, 2, or 1 deuterium atoms at chemical sites on the molecule of interest where protons would typically be expected. In some embodiments, the molecule of interest is partially deuterated (i.e., contains deuterium atoms at less than all chemical sites on the molecule of interest where protons would typically be expected). In some embodiments, the molecule of interest is fully deuterated (i.e., contains deuterium atoms at all chemical sites on the molecule of interest where protons would typically be expected).

In some embodiments, the molecule of interest comprises a partially or fully deuterated chemical analog of any biorelevant imaging agent. In some embodiments, the molecule of interest comprises a partially or fully deuterated chemical analog of pyruvate, alpha ketoglutarate, Z-4-methyl-2-oxopent-3-enedioc acid (Z-OMPD), zymonate, urea, azidothymidine (AZT), metronidazole, trimethylphenylammonium (TMPA), pyridine, nicotinamide, a diazirine tag, or conjugate acids thereof.

At step 320, the molecule of interest is located (i.e., placed) in a magnetic field. In some embodiments, the magnetic field has a mean magnetic field strength B₀. In some embodiments, B₀ is at least about 1 microtesla (μT), 2 μT, 3 μT, 4 μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 millitesla (mT), 2 mT, 3 mT, 4 mT, 5 mT, 6 mT, 7 mT, 8 mT, 9 mT, 10 mT, 20 mT, 30 mT, 40 mT, 50 mT, 60 mT, 70 mT, 80 mT, 90 mT, 100 mT, 200 mT, 300 mT, 400 mT, 500 mT, 600 mT, 700 mT, 800 mT, 900 mT, 1 tesla (T), 2 T, 3 T, 4 T, 5 T, or more. In some embodiments, B₀ is at most about 5 T, 4 T, 3 T, 2 T, 1 T, 900 mT, 800 mT, 700 mT, 600 mT, 500 mT, 400 mT, 300 mT, 200 mT, 100 mT, 90 mT, 80 mT, 70 mT, 60 mT, 50 mT, 40 mT, 30 mT, 20 mT, 10 mT, 9 mT, 8 mT, 7 mT, 6 mT, 5 mT, 4 mT, 3 ml, 2 mT, 1 mT, 900 μT, 800 μT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, or less. In some embodiments, B₀ is within a range defined by any two of the preceding values. For instance, in some embodiments, B₀ is between about 1 μT and about 1 T, about 1 μT and about 500 mT, about 1 μT and about 100 mT, about 1 μT and about 50 mT, about 10 μT and about 1 T, about 10 μT and about 500 mT, about 10 μT and about 100 mT, about 10 μT and about 50 mT, about 50 μT and about 1 T, about 50 μT and about 500 mT, about 50 μT and about 100 mT, about 50 μT and about 50 mT, about 100 μT and about 1 T, about 100 μT and about 500 mT, about 100 μT and about 100 mT, about 100 μT and about 50 mT, about 500 μT and about 1 T, about 500 μT and about 500 mT, about 500 μT and about 100 mT, about 1 mT and about 1 T, about 1 mT and about 500 mT, or about 1 mT and about 100 mT. In some embodiments, B₀ is generated using a magnetic shield (such as a mu metal magnetic shield) and a magnetic field source, such as a solenoid, other electromagnetic coil, or a permanent magnet.

At step 330, a coordination complex between the molecule of interest, a SABRE catalyst or pre-catalyst, and parahydrogen is formed. In some embodiments, the coordination complex is formed in the solution described herein with respect to step 320. In some embodiments, the SABRE catalyst or pre-catalyst comprises an iridium (Ir) catalyst or pre-catalyst, such as [IrCI(COD)(IMes)], where COD is cis,cis-1,5-cycloctadiene and IMes is 1,3-bis(2,4,6-trimethylphenyl)imidazol-2-ylidine, or a cobalt (Co) catalyst or pre-catalyst, such as (MesCCC)Co-py. In some embodiments, step 330 is performed in a solution comprising the molecule of interest, the SABRE catalyst or pre-catalyst, and the parahydrogen. In some embodiments, the parahydrogen is mixed into the solution using a mixing mechanism. In some embodiments, the mixing mechanism comprises a gas-liquid exchange mechanism. For example, the gas-liquid exchange mechanism may be a bubbler or a diffusion system. In some embodiments, the mixing mechanism comprises membranes adapted to permit diffusion of molecular hydrogen. In some embodiments, the parahydrogen is mixed into the solution at a pressure of at least about 1 bar, 2 bar, 3 bar, 4 bar, 5 bar, 6 bar, 7 bar, 8 bar, 9 bar, 10 bar, 20 bar, 30 bar, 40 bar, 50 bar, 60 bar, 70 bar, 80 bar, 90 bar, 100 bar, or more. In some embodiments, the parahydrogen is mixed into the solution at a pressure of at most about 100 bar, 90 bar, 80 bar, 70 bar, 60 bar, 50 bar, 40 bar, 30 bar, 20 bar, 10 bar, 9 bar, 8 bar, 7 bar, 6 bar, 5 bar, 4 bar, 3 bar, 2 bar, 1 bar, or less. In some embodiments, the parahydrogen is mixed into the solution at a pressure that is within a range defined by any two of the preceding values. For instance, in some embodiments, the parahydrogen is mixed into the solution at a pressure between 1 bar and 50 bar.

At step 340, an oscillating magnetic field is applied to the coordination complex. In some embodiments, the oscillating magnetic field has a maximum magnetic field strength B₁ is applied to the coordination complex. In some embodiments, applying the oscillating magnetic field transfers spin order from the parahydrogen to the molecule of interest. In some embodiments, transferring spin order from the parahydrogen to the molecule of interest increases the nuclear spin polarization of at least one nucleus in the molecule of interest. In some embodiments, the at least one nucleus comprises a ¹³C nucleus or a ¹⁵N nucleus.

In some embodiments, B₁ is at least about 0.1 μT, 0.2 μT, 0.3 μT, 0.4 μT, 0.5 μT, 0.6 μT, 0.7 μT, 0.8 μT, 0.9 μT, 1 μT, 2 μT, 3 μT, 4 μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 mT, 2 mT, 3 mT, 4 mT, 5 mT, 6 mT, 7 mT, 8 mT, 9 mT, 10 mT, or more. In some embodiments, B₁ is at most about 10 mT, 9 mT, 8 mT, 7 mT, 6 mT, 5 mT, 4 mT, 3 mT, 2 mT, 1 mT, 900 μT, 800 μT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, 0.9 μT, 0.8 μT, 0.7 μT, 0.6 μT, 0.5 μT, 0.4 μT, 0.3 μT, 0.2 μT, 0.1 μT, or less. In some embodiments, B₁ is within a range defined by any two of the preceding values. For instance, in some embodiments, B₁ is between about 0.1 μT and about 10 μT, about 0.1 μT and about 9 μT, about 0.1 μT and about 8 μT, about 0.1 μT and about 7 μT, about 0.1 μT and about 6 μT, about 0.1 μT and about 5 μT, about 0.1 μT and about 4 μT, about 0.1 μT and about 3 μT, about 0.1 μT and about 2 μT, about 0.1 μT and about 1 μT, about 0.1 μT and about 0.9 μT, about 0.1 μT and about 0.8 μT, about 0.1 μT and about 0.7 μT, about 0.1 μT and about 0.6 μT, about 0.1 μT and about 0.5 μT, about 0.1 μT and about 0.4 μT, about 0.1 μT and about 0.3 μT, about 0.1 μT and about 0.2 μT, about 0.2 μT and about 10 μT, about 0.2 μT and about 9 μT, about 0.2 μT and about 8 μT, about 0.2 μT and about 7 μT, about 0.2 μT and about 6 μT, about 0.2 μT and about 5 μT, about 0.2 μT and about 4 μT, about 0.2 μT and about 3 μT, about 0.2 μT and about 2 μT, about 0.2 μT and about 1 μT, about 0.2 μT and about 0.9 μT, about 0.2 μT and about 0.8 μT, about 0.2 μT and about 0.7 μT, about 0.2 μT and about 0.6 μT, about 0.2 μT and about 0.5 μT, about 0.2 μT and about 0.4 μT, about 0.2 μT and about 0.3 μT, about 0.3 μT and about 10 μT, about 0.3 μT and about 9 μT, about 0.3 μT and about 8 μT, about 0.3 μT and about 7 μT, about 0.3 μT and about 6 μT, about 0.3 μT and about 5 μT, about 0.3 μT and about 4 μT, about 0.3 μT and about 3 μT, about 0.3 μT and about 2 μT, about 0.3 μT and about 1 μT, about 0.3 μT and about 0.9 μT, about 0.3 μT and about 0.8 μT, about 0.3 μT and about 0.7 μT, about 0.3 μT and about 0.6 μT, about 0.3 μT and about 0.5 μT, about 0.3 μT and about 0.4 μT, about 0.4 μT and about 10 μT, about 0.4 μT and about 9 μT, about 0.4 μT and about 8 μT, about 0.4 μT and about 7 μT, about 0.4 μT and about 6 μT, about 0.4 μT and about 5 μT, about 0.4 μT and about 4 μT, about 0.4 μT and about 3 μT, about 0.4 μT and about 2 μT, about 0.4 μT and about 1 μT, about 0.4 μT and about 0.9 μT, about 0.4 μT and about 0.8 μT, about 0.4 μT and about 0.7 μT, about 0.4 μT and about 0.6 μT, about 0.4 μT and about 0.5 μT, about 0.5 μT and about 10 μT, about 0.5 μT and about 9 μT, about 0.5 μT and about 8 μT, about 0.5 μT and about 7 μT, about 0.5 μT and about 6 μT, about 0.5 μT and about 5 μT, about 0.5 μT and about 4 μT, about 0.5 μT and about 3 μT, about 0.5 μT and about 2 μT, about 0.5 μT and about 1 μT, about 0.5 μT and about 0.9 μT, about 0.5 μT and about 0.8 μT, about 0.5 μT and about 0.7 μT, about 0.5 μT and about 0.6 μT, about 0.6 μT and about 10 μT, about 0.6 μT and about 9 μT, about 0.6 μT and about 8 μT, about 0.6 μT and about 7 μT, about 0.6 μT and about 6 μT, about 0.6 μT and about 5 μT, about 0.6 μT and about 4 μT, about 0.6 μT and about 3 μT, about 0.6 μT and about 2 μT, about 0.6 μT and about 1 μT, about 0.6 μT and about 0.9 μT, about 0.6 μT and about 0.8 μT, about 0.6 μT and about 0.7 μT, about 0.7 μT and about 10 μT, about 0.7 μT and about 9 μT, about 0.7 μT and about 8 μT, about 0.7 μT and about 7 μT, about 0.7 μT and about 6 μT, about 0.7 T and about 5 μT, about 0.7 μT and about 4 μT, about 0.7 μT and about 3 μT, about 0.7 μT and about 2 μT, about 0.7 μT and about 1 μT, about 0.7 μT and about 0.9 μT, about 0.7 μT and about 0.8 μT, about 0.8μT and about 10 μT, about 0.8 μT and about 9 μT, about 0.8 μT and about 8 μT, about 0.8 μT and about 7 μT, about 0.8 μT and about 6 μT, about 0.8 μT and about 5 μT, about 0.8 μT and about 4 μT, about 0.8 T and about 3 μT, about 0.8 μT and about 2 μT, about 0.8 μT and about 1 μT, about 0.8 μT and about 0.9 μT, about 0.9 μT and about 10 μT, about 0.9 μT and about 9 μT, about 0.9 μT and about 8 μT, about 0.9 μT and about 7 μT, about 0.9 μT and about 6 μT, about 0.9 T and about 5 μT, about 0.9 μT and about 4 μT, about 0.9 μT and about 3 μT, about 0.9 μT and about 2 μT, about 0.9 μT and about 1 μT, about 1 μT and about 10 μT, about 1 μT and about 9 μT, about 1 μT and about 8 μT, about 1 μT and about 7 μT, about 1 μT and about 6 μT, about 1 μT and about 5 μT, about 1 μT and about 4 μT, about 1 μT and about 3 μT, about 1 μT and about 2 μT, about 2 μT and about 10 μT, about 2 μT and about 9 μT, about 2 μT and about 8 μT, about 2 μT and about 7 μT, about 2 T and about 6 μT, about 2 μT and about 5 μT, about 2 μT and about 4 μT, about 2 μT and about 3 μT, about 3 μT and about 10 μT, about 3 μT and about 9 μT, about 3 μT and about 8 μT, about 3 μT and about 7 μT, about 3 μT and about 6 μT, about 3 μT and about 5 μT, about 3 μT and about 4 μT, about 4 μT and about 10 μT, about 4 μT and about 9 μT, about 4 μT and about 8 μT, about 4 μT and about 7 μT, about 4 μT and about 6 μT, about 4 μT and about 5 μT, about 5 μT and about 10 μT, about 5 μT and about 9 μT, about 5 μT and about 8 μT, about 5 μT and about 7 μT, about 5 μT and about 6 μT, about 6 μT and about 10 μT, about 6 μT and about 9 μT, about 6 μT and about 8 μT, about 6 μT and about 7 μT, about 7 μT and about 10 μT, about 7 μT and about 9 μT, about 7 μT and about 8 μT, about 8 μT and about 10 μT, about 8 μT and about 9 μT, or about 9 μT and about 10 μT.

In some embodiments, the oscillating magnetic field is generated by a waveform generator. The waveform generator may include one more computing unit, processors, controllers, associate memories, PCs, computers services, or any devices capable of carrying computational operations using inputs and producing outputs.

The oscillating magnetic field can be applied to the coordination complex using RF coils. The RF coils can be disposed around the chamber in which the SABRE polarization transfer was performed. The RF coils may have one or more channels. Such channels may be pathways for applying the RF signals to the coordination complex. There may be provided at least one channel for each different type of nuclear spin species. In some embodiments, there may be at least one proton (H) channel and/or at least one channel for another nuclear spin species (e.g., ²H, ³H, ¹³C, ¹⁵N, ¹⁹F, ³¹P, or other suitable species). In some embodiments, the RF waveforms applied to the ¹H channel and each of the channel(s) for the other nuclear spin species may differ. In some embodiments, the at least one proton channel is used to selectively address one of the ¹H spins. In some embodiments, the RF waveforms on the ¹H channel and/or each of the channel(s) for the other nuclear spin species (e.g., a ²H, ¹³C, and/or ¹⁵N channel) are configured to apply a polarization transfer sequence, such as PulsePol, ADAPT, PH-INEPT, Goldman's sequence, S2M, S2hM or ESOTERIC.

In some embodiments, any one, two, three, or four of steps 310, 320, 330, and 340 are performed in a magnetic shield, such as a mu metal magnetic shield.

In some embodiments, the method 300 imparts a nuclear spin polarization to at least one nucleus of the molecule of interest. In some embodiments, the nuclear spin polarization is at least about 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, or more. In some embodiments, the nuclear spin polarization is at most about 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, or less. In some embodiments, the nuclear spin polarization is within a range defined by any two of the preceding values.

In some embodiments, the method 300 is performed at a temperature of at least about 30 degrees Centigrade (° C.), −25° C., −20° C., −15° C., −10° C., −5 ° C., 0° C., 5° C., 10° C., 15° C., 20° C., or more, at most about 20° C., 15° C., 10° C., 5° C., 0° C., −5° C., −10° C., −15° C., −20° C., −25 ° C., −30° C., or less, or at a temperature that is within a range defined by any two of the preceding values.

In some embodiments, SABRE catalyst or pre-catalyst can be extracted from the solution, or undesired solutes can be removed from the solution. The disclosed embodiments are not limited to any particular method of separating the SABRE catalyst or pre-catalyst. In some embodiments, the separation is performed by liquid-liquid separation. In some embodiments, the SABRE catalyst or pre-catalyst (or the undesired solutes) can be extracted from the solution by precipitation or solidification. Such precipitation or solidification can be induced reducing the solubility of the SABRE catalyst or pre-catalyst in the solution. In some embodiments, the solution can be modified (e.g., by changing solution pH, temperature, adding other solvents or solutes, or the like). In some embodiments, application of an electromagnetic stimulus (e.g., optical radiation, such as ultraviolet radiation or optical radiation at another suitable wavelength or wavelengths) or mechanical stimulus (e.g., ultrasound, agitation, or another suitable mechanical stimulus), addition of another solute or solvent to the solution, or another suitable method. In some embodiments, following precipitation, the SABRE catalyst or pre-catalyst can be separated from the solution (e.g., using a filter, centrifuge, or another suitable method).

In some embodiments, the molecule of interest can be used in an NMR or MRI application. In some embodiments, at least a portion of the molecule of interest can be injected into a subject or patient for use in MRI imaging of the subject or patient. In various embodiments, at least a portion of the molecule of interest can be used in NMR spectroscopy.

### Compositions Featuring an Increased Nuclear Spin Polarization in Molecules of Interest Polarized by SABRE Methods

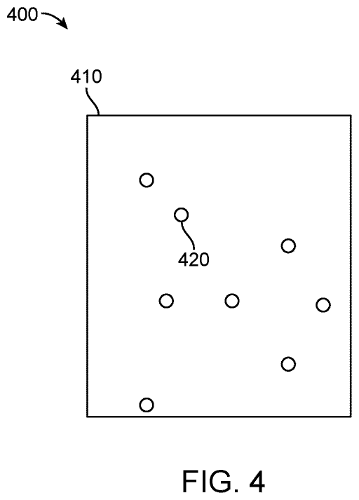

FIG. 4 depicts a composition 400 featuring an increased nuclear spin polarization in a molecule of interest polarized by a SABRE method, in accordance with disclosed embodiments. In the example shown, the composition 400 comprises a solution 410 and a hyperpolarized molecule of interest 420. In some embodiments, the solution 410 comprises any solution described herein with respect to FIG. 3. In some embodiments, the hyperpolarized molecule of interest 420 comprises any hyperpolarized molecule of interest described herein with respect to FIG. 3. In some embodiments, the solution is for use in any NMR or MRI procedure described herein with respect to FIG. 3, such as any SABRE procedure described herein with respect to FIG. 3.

In some embodiments, the composition 400 is generated using the method 300 described herein with respect to FIG. 3. That is, in some embodiments, the composition 400 is generated by: (a) obtaining a molecule of interest comprising at least one deuterium atom; (b) locating the molecule of interest in a magnetic field having a mean magnetic field strength (B₀) of at most about 2 Tesla (T); (c) forming a coordination complex between the molecule of interest, a signal amplification by reversible exchange (SABRE) catalyst or pre-catalyst, and parahydrogen; and (d) applying an oscillating magnetic field to the coordination complex to thereby transfer spin order from the parahydrogen to the molecule of interest and to thereby increase the nuclear spin polarization of at least one atom in the molecule of interest.

In some embodiments, the molecule of interest comprises any molecule of interest described herein with respect to FIG. 3. In some embodiments, the mean magnetic field strength is any mean magnetic field strength described herein with respect to FIG. 3. In some embodiments, the SABRE catalyst or pre-catalyst comprises any SABRE catalyst or pre-catalyst described herein with respect to FIG. 3. In some embodiments, the oscillating magnetic field comprises any oscillating magnetic field described herein with respect to FIG. 3. In some embodiments, (a)-(d) are performed in a magnetic shield. In some embodiments, (c) is performed in a solution comprising the molecule of interest, the SABRE catalyst or pre-catalyst, and the parahydrogen. In some embodiments, the composition is generated by bubbling the parahydrogen into the solution. In some embodiments, the parahydrogen is bubbled into the solution at any pressure of at any pressure described herein with respect to FIG. 3. In some embodiments, subsequent to (d), the nuclear spin polarization in the molecule of interest is any nuclear spin polarization described herein with respect to FIG. 3.

### Biorelevant Imaging Agents

The disclosed embodiments include methods for producing and utilizing biorelevant imaging agents with clinically relevant polarizations, concentrations, volumes, or purities. In some embodiments, the method is for preparing an NMR material (also referred to herein as a “molecule of interest”). In some embodiments, the NMR material is suitable for use in NMR or MRI operations. In some embodiments, the NMR material increases NMR or MRI signal and signal-to-noise ratio (SNR). In some embodiments, the NMR material is suitable for use in solution NMR spectroscopy. In some embodiments, the NMR material is a chemical compound. In some embodiments, the NMR material is a metabolite (e.g., a molecule with a biological relevance such as an amino acid, a saccharide, a derivative thereof, or the like), such as a metabolite suitable for use in an NMR metabolomics application. In some embodiments, the NMR material is suitable for in-vitro probing of the metabolism of a cell culture or other biological tissue. In some embodiments, the NMR material is used in an NMR probe to investigate a transient effect in which high signal enhancement due to hyperpolarization is needed, such as proton exchange between water and biomolecules. In some embodiments, the NMR material is a small molecule or metabolite suitable for injection into a cell, tissue or organism for detection in an MRI scan. In some embodiments, the NMR material is introduced into a chamber for further analysis by NMR or MRI operations. In some embodiments, the NMR material is enriched with one or more deuterium (²H), carbon-13 (¹³C), or nitrogen-15 (¹⁵N) atoms.

Consistent with disclosed embodiments, NMR material can include biorelevant imaging agents. In some embodiments, the biorelevant imaging agent can be suitable for use in NMR or MRI operations. In some embodiments, the biorelevant imaging agent may increase NMR or MRI signal or signal-to-noise ratio (SNR). In some embodiments, the biorelevant imaging agent can be suitable for use in solution NMR spectroscopy. In some embodiments, the biorelevant imaging agent may be a metabolite (e.g., a molecule with a biological relevance such as an amino acid, a saccharide, a derivative thereof, or the like), such as a metabolite suitable for use in an NMR metabolomics application. In some embodiments the biorelevant imaging agent is used for perfusion imaging or contrast enhanced imaging in MRI scans. In some embodiments, the biorelevant imaging agent is suitable for in-vitro probing of the metabolism of a cell culture or other biological tissue. In some embodiments, the biorelevant imaging agent is used for in-vitro probing of the metabolism of a cell culture or other biological tissue. In some embodiments, the biorelevant imaging agent is used in an NMR probe to investigate a transient effect in which high signal enhancement due to hyperpolarization is needed, such as proton exchange between water and biomolecules. In some embodiments, the biorelevant imaging agent is a small molecule or metabolite suitable for injection into a cell, tissue or organism for detection in an MRI scan. In some embodiments, the biorelevant imaging agent is introduced into a chamber for further analysis by NMR or MRI operations. In some embodiments, the biorelevant imaging agent is enriched with one or more ²H, ¹³C, or ¹⁵N atoms.

In some embodiments, the biorelevant imaging agent comprises pyruvate, lactate, alpha-ketoglutarate, bicarbonate, fumarate, urea, dehydroascorbate, glutamate, glutamine, acetate, dihydroxyacetone, acetoacetate, glucose, ascorbate, zymonate, alanine, fructose, imidazole, nicotinamide, nitroimidazole, pyrazinamide, isoniazid, a conjugate acid of any of the foregoing, natural and unnatural amino acids, esters thereof, or ²H, ¹³C, or nitrogen-15(¹⁵ N) enriched versions of any of the foregoing. In some embodiments, the biorelevant imaging agent comprises pyruvate, lactate, alpha-ketoglutarate. In some embodiments, the biorelevant imaging agent comprises pyruvate. In some embodiments, the biorelevant imaging agent comprises lactate. In some embodiments, the biorelevant imaging agent comprises alpha-ketoglutarate (e.g., ethyl alpha-ketoglutarate).

In some embodiments, the biorelevant imaging agent comprises at least one non-hydrogen nuclear spin. In some embodiments, the non-hydrogen nuclear comprises at least one spin-1/2 atom. In some embodiments, the non-hydrogen nuclear spin comprises ¹³C or ¹⁵N. In some embodiments, the biorelevant imaging agent is at least partially isotopically labeled with the non-hydrogen nuclear spin. In some embodiments, the biorelevant imaging agent is at least partially enriched with the non-hydrogen nuclear spin when compared to an analog of the biorelevant imaging agent that features the non-hydrogen nuclear spin at its natural abundance. In some embodiments, the biorelevant imaging agent is enriched to feature the non-hydrogen nuclear spin at an abundance of at least about 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 91%, 92%, 93%, 94%, 95%, 96%, 97%, 98%, 99%, or more, at most about 99%, 98%, 97%, 96%, 95%, 94%, 93%, 92%, 91%, 90%, 85%, 80%, 75%, 70%, 65%, 60%, 55%, 50%, 45%, 40%, 35%, 30%, 25%, 20%, 15%, 10%, 9%, 8%, 7%, 6%, 5%, 4%, 3%, 2%, 1%, or less, or an abundance that is within a range defined by any two of the preceding values.

In some embodiments, the non-hydrogen nuclear spin replaces an NMR-inactive (i.e., spin-0) nucleus (e.g., ¹²C or a quadrupolar (i.e., spin>1/2) nucleus (e.g., nitrogen-14, ¹⁴N) of the analog of the biorelevant imaging agent that features the non-hydrogen nuclear spin at its natural abundance. For example, an analog of pyruvate that features ¹³C at its natural abundance may include about 98.9% ¹²C and about 1.1% ¹³C at either C* in the structure H₃C-C*(═O)-C*OOH. As a biorelevant imaging agent, pyruvate may instead be isotopically enriched with ¹³C such that one or both C* comprises ¹³C at any abundance described herein. As used herein, *C and C* describe a carbon that can be either a ¹²C or ¹³C carbon isotope. As another example, an analog of urea that features ¹⁵N at its natural abundance may include about 99.6% ¹⁴N and about 0.4% ¹⁵N at either N* in the structure H₂N *-C(═O)-*NH₂. As a biorelevant imaging agent, urea may instead be isotopically enriched with ¹⁵N such that one or both N* comprises ¹⁵N at any abundance described herein. As used herein, *N and N* describe a nitrogen that can be either a ¹⁴N or ¹⁵N nitrogen isotope.

### EXAMPLES

### Example 1: Increased Concentration of a Molecule of Interest in Solution

Experiments were performed using dimethyl acetylenedicarboxylic acid (DMAD, also known as dimethyl 2-butynedioate). DMAD is a precursor that, when hydrogenated, yields dimethyl maleate (DMM). The goal of the initial experiments was to show that it is possible to reduce the solution by a factor of at least 2 (e.g., a factor of between 2 and 2.5) while retaining sufficient nuclear spin polarization and still having enough solution for automated injection into an NMR spectrometer.

In a first experiment, evaporation was performed using a manual procedure. 0.5 M DMAD precursor was dissolved in acetone-d₆. 1 milliliter (mL) of the precursor was injected into a reactor. The solution was heated to 50 degrees Celsius (° C.). The solution was purged with nitrogen (N₂) gas at 4 bar for 3 seconds. The precursor was then hydrogenated in the solution at 10 bar for 5 seconds. The solution was purged with N₂ gas again for 3 seconds. The reactor was manually opened to vacuum just before the heater on the reactor ramped the temperature for boil off. The reactor was then closed to vacuum, vented, and the remaining solution was manually extracted. The composition was characterized by NMR.

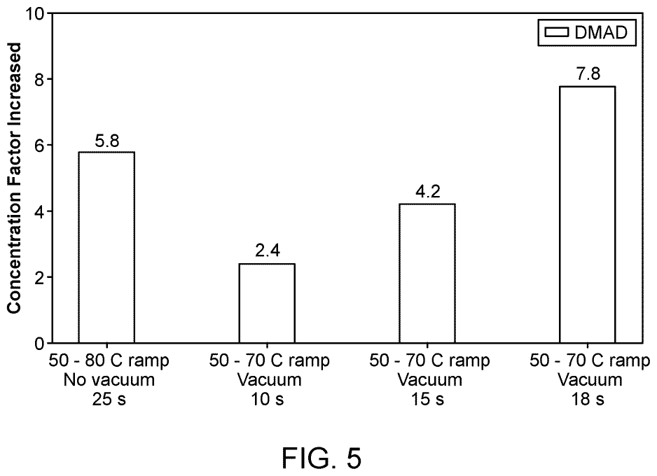

FIG. 5 shows the results for the manual tests with 1 mL precursor solution, manual extraction of the remaining solution from the reactor, and characterization of the evaporation by NMR. As shown in FIG. 5, evaporation allowed an increase in the concentration of DMAD by a factor of 2.4 to 7.8, depending on temperature, vacuum, and time conditions.

In a second experiment, evaporation was performed using an automated system. 0.2 M DMAD precursor was dissolved in acetone-d 6. 2 mL of the precursor was injected into a reactor. The solution was heated to 50° C. The solution was purged with N₂ gas at 4 bar for 3 seconds. The precursor was then parahydrogenated in the solution using parahydrogen gas at 10 bar for 5 seconds. The solution was purged with N₂ gas again for 3 seconds. The heater ramped temperature for boil off. An audio frequency sweep was applied to convert singlet state polarization to magnetization. The system opened the reactor to vacuum for boil off. The reactor was closed to vacuum, vented, and the solution was injected to an NMR spectrometer for measurement.

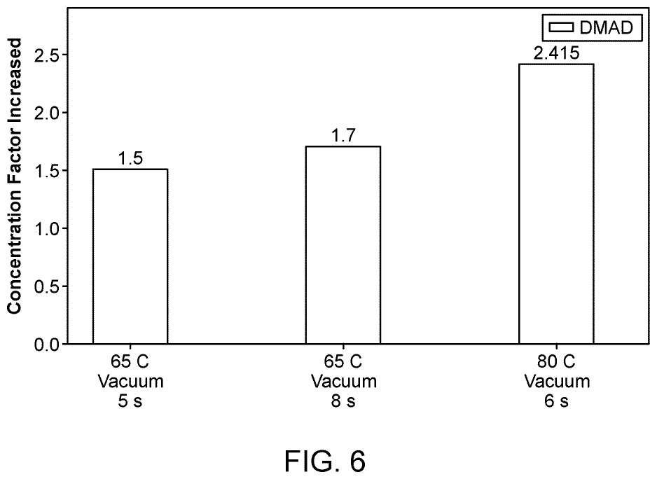

FIG. 6 shows the results of automated tests with 2 mL precursor solution. As shown in FIG. 6, evaporation allowed an increase in the concentration of DMAD by a factor of 1.7 to 2.415, depending on temperature, vacuum, and time conditions.

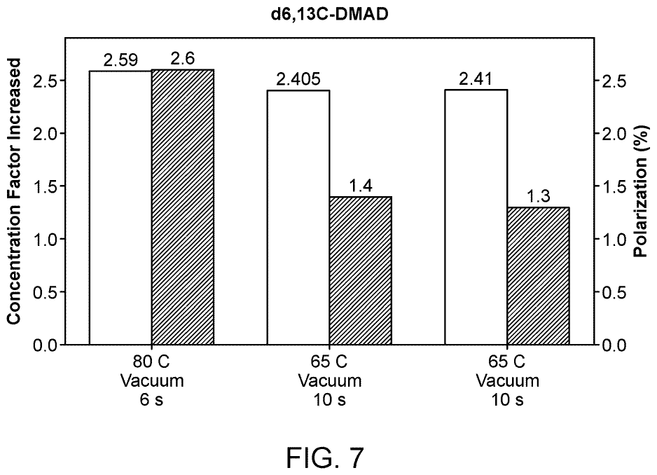

FIG. 7 shows the results of automated tests with a 2 mL precursor solution of deuterium and carbon-labeled DMAD (d₆, ¹³C). As shown in FIG. 7 evaporation allowed an increase in the concentration of DMAD by a factor of 2.405 to 2.59 (as shown in the white bars), while maintaining a nuclear spin polarization of 1.3% to 2.6% (as shown in the filled bars), depending on temperature, vacuum, and time conditions.

### Example 2: Increased Nuclear Spin Polarization in Molecules of Interest Polarized by SABRE methods

Methods for increasing the hyperpolarization of pyruvate produced by SABRE processes were investigated. In SABRE, polarization transfer from parahydrogen to ¹³C is mediated by indirect dipolar couplings (J-couplings) between nuclei in transient complexes. For SABRE, the ultralow magnetic field regime (e.g., mean magnetic field magnitude of hundreds of nanotesla over a sample) plays an important role. At these fields, nuclear spin energy states of the molecules are matching and the J-coupling interaction effectively perturbs the eigenstates such that energy level crossing is avoided (i.e., the system energy states display level anti crossing (LAC)). When a SABRE reaction is carried out at the LAC, the target ¹³C spin is spontaneously hyperpolarized. Methods that rely on such LACs are referred to as SABRE-SHEATH (SABRE in shield enables alignment transfer to heteronuclei) and have been used to polarize [1-¹³C]pyruvate. More recently, pulsed static fields have been used to induce this effect, delivering similar ¹³C polarization (P_{13C}) for [1-¹³C]pyruvate as SABRE-SHEATH. Pulsed radiofrequency (rf) fields can be employed for polarization transfer. Spin-lock induced crossing (SLIC) by continuous rf irradiation at tesla fields has also been applied along with SABRE and was termed low-irradiation generation of high tesla- (LIGHT-) or SLIC-SABRE. However, the P_{13C} achieved by high-field SLIC-SABRE were found to be lower than those obtained via SABRE-SHEATH. Such low P_{13C} may result from the fact that SLIC at high (e.g., a few hundred millitesla to a few tesla) fields faces significant challenges such as often unfavorable relaxation dynamics due to chemical shift anisotropy (CSA), singlet-to-triplet mixing of parahydrogen, and a need for selective excitation of bound and free SABRE species due to larger chemical shift dispersion.

In sharp contrast, at much lower (e.g., a few microtesla) fields, ¹³C chemical shift differences between the bound and free SABRE species are negligible and relaxation times become favorable. Thus, we used SLIC-SABRE at microtesla fields to quickly hyperpolarize [1-¹³C] pyruvate-d₃ and [2-¹³C]pyruvate-d₃, obtaining ¹³C polarizations of P_{13C}=22% and P_{13C}=6%, respectively. To achieve such high P_{13C} levels, we performed the SABRE reaction by bubbling parahydrogen gas through a solution of ~30 mM pyruvate-ds in CD₃OD at 50 μT and at ~3-7° C. in the presence of a spin-lock induced crossing (SLIC) rf field. Pyruvate-d₃ (and pyruvate-h₃ below) was used with natural ¹³C abundance (1.1%) to minimize sample-to-sample variability; no difference in P_{13C} values between ¹³C-labeled and natural-abundance samples was observed. After the SLIC process, an adiabatic 90° pulse was used to align the ¹³C polarization longitudinally along the 50 μT field, and the sample was moved from the SABRE setup to an 80 MHz benchtop NMR system for ¹³C signal acquisition. A detailed description of the setup and method is presented below.

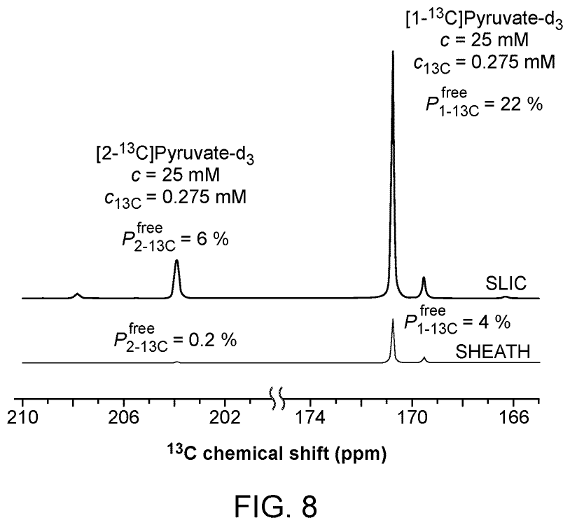

FIG. 8 shows exemplary ¹³C NMR spectra of [1-¹³C]pyruvate-ds and [2-¹³C]pyruvate-d₃ polarized using the SLIC-SABRE methods described herein and the prior gold standard SABRE-SHEATH method. As shown in FIG. 8, the SLIC-SABRE method drastically outperforms the SABRE-SHEATH method, and yields pyruvate polarization levels two to six times higher than any other previous SABRE process.

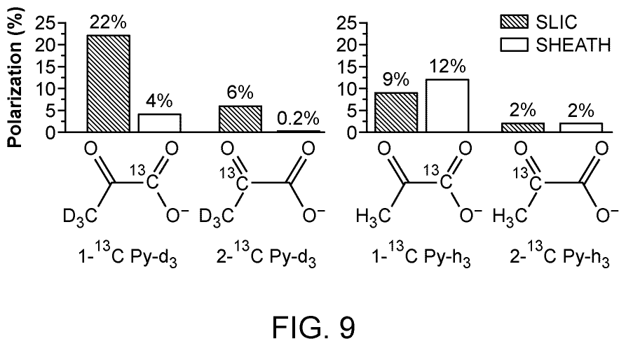

To better understand why SLIC-SABRE at microtesla fields shows such high efficacy, we carried out experiments using both protonated and deuterated pyruvate and using both SLIC-SABRE and SABRE-SHEATH. FIG. 9 shows exemplary ¹³C polarization levels for protonated and deuterated [1-¹³C]pyruvate and [2-¹³C]pyruvate polarized using the SLIC-SABRE methods described herein and SABRE-SHEATH. Protonated [1-¹³C]pyruvate and [2-¹³C]pyruvate show similar P_{13C} values for each polarization protocol: 12% versus 9% for [1-¹³C]pyruvate, and 2% in both cases for [2-¹³C]pyruvate. However, we found that SLIC-SABRE performed much better for pyruvate-d₃: P_{13C} using SABRE-SHEATH (at 0.4 μT) was 4% and 0.2% for [1-¹³C]pyruvate-ds and [2-¹³C]pyruvate-d3, but P_{13C} using SLIC-SABRE increased to 22% and 6%, respectively.

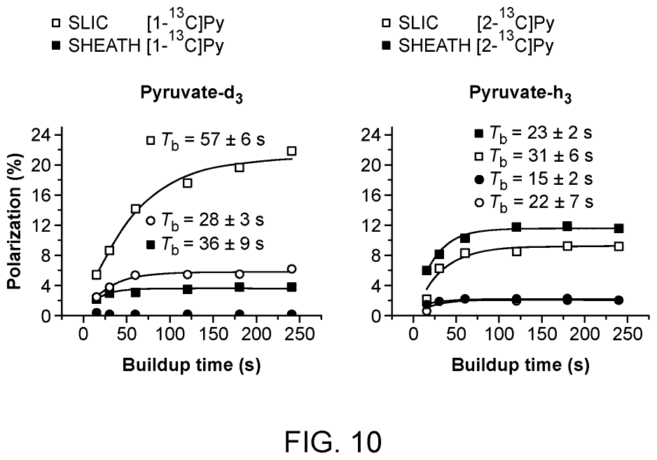

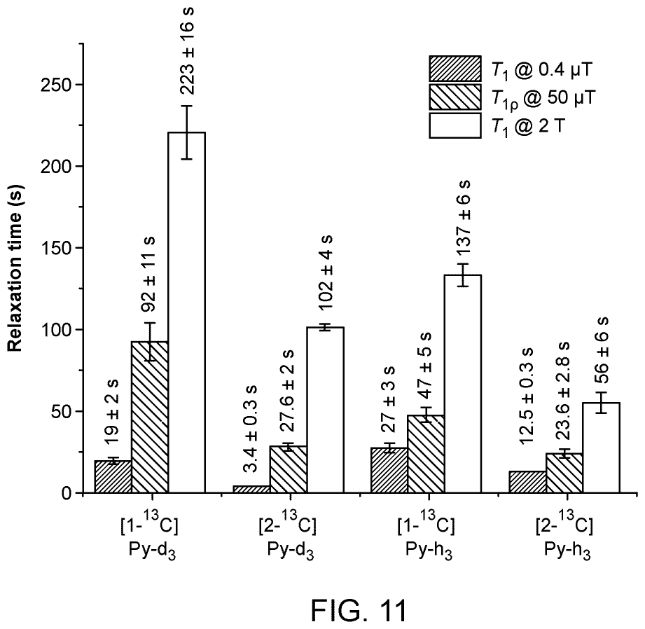

Without limiting the scope of the disclosure, we posit that these results occur because the deuterium nuclei have two distinct effects on relaxation. Firstly, at ultralow fields the deuterons are strongly coupled to the ¹³C spins and act as a quadrupolar relaxation sink. This is the case during SABRE-SHEATH, and is particularly detrimental for the C2 carbon, which has stronger J-couplings to the deuterons than the C1 carbon. Secondly, the deuterons reduce the rate of intramolecular dipole-dipole relaxation experienced by the ¹³C spins since the magnetic moments of deuterons are smaller than those of protons. This effect manifests in higher ¹³C polarizations and more favorable polarization build-up kinetics, which are shown in FIG. 10. To support this hypothesis, we also present measured T₁ and T_{1ρ} values and find that T_{1ρ} at 50 μT is longer than T₁ at 0.4 μT for all investigated pyruvate isotopologues (shown in FIG. 11), ultimately enabling effective polarization buildup. Thus, for the pyruvate-d₃ isotopologues whose T₁ under SABRE-SHEATH and T_{1ρ} under SLIC-SABRE conditions differ most, much higher polarizations are achieved using SLIC-SABRE. We envision that further analysis of the polarization transfer in the SABRE exchange complex during SLIC and experimental parameter optimization (such as reaction temperature, static magnetic field, and SLIC rf field) will enable even greater signal enhancements,

Notably, deuterium isotope labelling can also prolong T₁ relaxation at clinical magnetic fields. The longer polarization lifetime gained by deuteration will be conducive to yielding high P_{13C} after purification, quality assurance, and injection of the hyperpolarized pyruvate or other biorelevant imaging agent. Importantly, no deuterium isotope effect on metabolic conversion kinetics has been observed for pyruvate, meaning that for metabolic MRI pyruvate-d₃ can successfully be used instead of non-deuterated pyruvate. Notably, both isotopically-enriched [1-₁₃C]pyruvate-d₃ and [2-¹³C]pyruvate-d₃ are commercially available and no further chemical modification is needed for SABRE. This is in sharp contrast to hydrogenative parahydrogen-based hyperpolarization approaches that require suitable unsaturated molecular precursors. Additionally, due to the low cost and simplicity of SABRE hardware, this approach can be widely available to researchers. Considering recent advances on rapidly extracting SABRE-polarized pyruvate from methanol into catalyst-free aqueous solution, the first preclinical metabolic MRI studies using this technique appear on the near horizon.

For all experiments, samples containing 30 mM sodium pyruvate or sodium pyruvate-d₃, 6 mM IrIMes(cod)Cl, and 40 mM dimethyl sulfoxide (DMSO) in methanol-d₄ were prepared. After mixing the constituents, the samples were sonicated for 5 minutes (min). If residual particles were visible in the solutions, they were filtered with a 0.45 μm polytetrafluoroethylene (PTFE) syringe filter. The solutions were then degassed by bubbling of N₂ gas. The IrIMes(cod)CI SABRE catalyst was synthesized according to known procedures. Each sample was activated by bubbling parahydrogen gas through it for 10 min at 10 bar.

The samples were filled into NMR pressure tubes and connected to a gas system that allows for automatic injection of gas. For generation of hyperpolarization, the samples were placed into an apparatus consisting of a mu metal shield (which shields the external magnetic field), a piercing solenoid (which provides a static magnetic field along the z-axis B₀), and coils along the x-axis (B₁) (which generate a linearly polarized, oscillating magnetic field along the X-axis).

For SABRE-SHEATH experiments, a static magnetic field of 400 nanotesla (nT) was applied to the sample for a bubbling time tp to allow polarization to build up during bubbling. Subsequently, the magnetic field was suddenly increased to 30 μT to stop the SABRE hyperpolarization process and allow for sample extraction through the mu-metal shield. For SLIC-SABRE, a static magnetic field of 50 μT was applied to the sample. To facilitate polarization transfer, during bubbling of parahydrogen, an oscillating B₁ field with an amplitude of 1.8 μT was applied to the sample at the Larmor frequency (535.25 Hertz, Hz) of the ¹³C spins. During this time, polarization rotating with the magnetic field in the x-y plane was generated. Subsequently, a half passage adiabatic 90-degree pulse with a starting amplitude of 4 μT was used to rotate the magnetization parallel to the z-axis. The pulse amplitude was linearly ramped down from 4 μT to 0 within 2 seconds. At the same time, the frequency of the B₁ field was linearly ramped up by 50 Hz.

All experiments were automated by the Qudi software package for experimental control. After build-up of hyperpolarization, the samples were manually transferred to a Bruker F80 benchtop NMR spectrometer (Bruker) for measurements of ¹³C NMR spectra.

After completion of the SABRE experiments, the concentration of the free and bound pyruvate in solution was determined by ¹H NMR or ²H NMR in the case of pyruvate and pyruvate-d₃, respectively. In the case of pyruvate, an external reference standard consisting of 40 mM DMSO in methanol was used. For pyruvate-d₃ the integral of the CD₃ lines of the solvent was used as a reference. Nuclear spin polarization of hyperpolarized samples was determined by calibration against an external reference (1-¹³C methanol, 99%). The polarization P_{hyp} was calculated according to P_{hyp}=S_{hyp}/S_{ref}·[C_{ref}]/[C_{hyp}]·P_{ref}. Here, S_{hyp}, S_{ref}, [C_{ref}], and [C_{hyp}] are the signals and concentrations of the hyperpolarized sample and the reference sample, respectively. P_{ref} is the thermal equilibrium Boltzmann polarization of the reference sample at the 1.9 T measurement field of the F80 spectrometer at room temperature.

For the measurement of T1 at 1.88 T, a hyperpolarized sample was inserted into the F80 NMR spectrometer and ¹³C NMR spectra were recorded every 10 s using a 10 degree flip angle for excitation. The consumption of 13C signal by previous excitation pulses was later corrected before fitting the data. For the measurements of T₁ at 0.4 μT, the samples were hyperpolarized using SABRE-SHEATH or SLIC-SABRE for generation of hyperpolarized signals. Note that SLIC-SABRE was used for hyperpolarization of the deuterated pyruvate isotopologue because of the higher polarization yield. Subsequently, the parahydrogen supply to the sample was stopped and the sample was allowed to further evolve for 20 s to minimize any effects of residual buildup of SABRE magnetization during the relaxation delay. Subsequently, the field was dropped to 0.4 μT and the sample was allowed to relax for different time before being transferred to the NMR spectrometer for measurement of ¹³C NMR spectra. This procedure was repeated for each timepoint reported. The measurement of T_{1ρ} data was done in the same way, but here the sample was kept at 50 μT external field and the magnetization was spin-locked with an amplitude of B₁=1.86 μT for the different times reported before the magnetization was flipped back along the z-axis of the static magnetic field and the sample was transferred to the NMR for acquisition of ¹³C spectra.

To quantify the error of the SABRE experiments using our setup and sample preparation, we representatively repeated the SLIC-SABRE hyperpolarization of pyruvate-d₃ N=5 times. Each sample was prepared independently. Pyruvate concentration was determined and polarization quantified as described in the experimental section above. We found a mean [1-¹³C]pyruvate-d₃ polarization of 21.4±0.6 %.

The foregoing description has been presented for purposes of illustration. It is not exhaustive and is not limited to precise forms or embodiments disclosed. Modifications and adaptations of the embodiments will be apparent from consideration of the specification and practice of the disclosed embodiments. For example, the described implementations include hardware, but systems and methods consistent with the present disclosure can be implemented with hardware and software. In addition, while certain components have been described as being coupled to one another, such components may be integrated with one another or distributed in any suitable fashion.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application, which examples are to be construed as nonexclusive. Further, the steps of the disclosed methods can be modified in any manner, including reordering steps or inserting or deleting steps.

The features and advantages of the disclosure are apparent from the detailed specification, and thus, it is intended that the appended claims cover all systems and methods falling within the true spirit and scope of the disclosure. As used herein, the indefinite articles “a” and “an” mean “one or more.” Similarly, the use of a plural term does not necessarily denote a plurality unless it is unambiguous in the given context. Further, since numerous modifications and variations will readily occur from studying the present disclosure, it is not desired to limit the disclosure to the exact construction and operation illustrated and described, and accordingly, all suitable modifications and equivalents may be resorted to, falling within the scope of the disclosure.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

### RECITATION OF EMBODIMENTS

Embodiment 1. A method for performing a magnetic resonance imaging (MRI) or nuclear magnetic resonance (NMR) procedure using a hyperpolarized molecule of interest, the method comprising:
(a) obtaining an organic solution having the hyperpolarized molecule of interest dissolved therein at a first concentration;
(b) evaporating at least a portion of the organic solution to thereby generate an organic solution having the hyperpolarized molecule of interest dissolved therein at a second concentration greater than the first concentration; and
(c) performing the MRI or NMR procedure using the hyperpolarized molecule of interest.

Embodiment 2. The method of Embodiment 1, wherein the first concentration is less than 100 millimolar (mM), 90 mM, 80 mM, 70 mM, 60 mM, 50 mM, 40 mM, 30 mM, 20 mM, 10 mM, or less.

Embodiment 3. The method of Embodiment 1 or 2, wherein the second concentration is at least 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, or more.

Embodiment 4. The method of any one of Embodiments 1-3, wherein the organic solution comprises at least one organic molecule selected from the group consisting of: methanol, ethanol, n-propanol, isopropanol, and acetone.

Embodiment 5. The method of any one of Embodiments 1-4, wherein (b) comprises evaporating at least the portion by performing at least one evaporation procedure selected from the group consisting of: flowing an inert gas across the organic solution, subjecting the organic solution to vacuum, and heating the organic solution.

Embodiment 6. The method of any one of Embodiments 1-5, wherein (a)-(b) are conducted for a total period of at most 150 seconds(s), 140 s, 130 s, 120 s, 110 s, 100 s, 90 s, 80 s, 70 s, 60 s, 50 s, 40 s, 30 s, 20 s, 19 s, 18 s, 17 s, 16 s, 15 s, 14 s, 13 s, 12 s, 11 s, 10 s, 9 s, 8 s, 7 s, 6 s, 5 s, 4 s, 3 s, 2 s, 1 s, or less.

Embodiment 7. The method of any one of Embodiments 1-6, wherein immediately following (a), at least one nucleus of the hyperpolarized molecule of interest has a first nuclear spin polarization, wherein immediately prior to (c), the at least one nucleus of the hyperpolarized molecule of interest has a second nuclear spin polarization, and wherein the second nuclear spin polarization is reduced from the first nuclear spin polarization by no more than 10%, 20%, 30%, 40%, or 50%.

Embodiment 8. The method of any one of Embodiments 1-7, further comprising, prior to (a), generating the hyperpolarized molecule of interest using at least one hyperpolarization procedure selected from the group consisting of: parahydrogen induced polarization (PHIP), PHIP-sidearm hydrogenation (PHIP-SAH), PHIP nuclear Overhauser effect system (PHIPNOESYS), and signal amplification by reversible exchange (SABRE).

Embodiment 9. The method of any one of Embodiments 1-8, wherein the hyperpolarized molecule of interest is selected from the group consisting of: dimethyl maleate, pyruvate, glutamate, glutamine, lactate, acetate, acetoacetate, zymonate, alanine, fructose, fumarate, bicarbonate, urea, dehydroascorbate, alpha-ketoglutarate, dihydroxyacetone, glucose, ascorbate, and conjugate acids thereof.

Embodiment 10. The method of any one of Embodiments 1-9, wherein (c) comprises performing the MRI or NMR procedure using the organic solution.

Embodiment 11. The method of any one of Embodiments 1-9, further comprising, subsequent to (b), mixing the organic solution with water to thereby generate an aqueous solution having the hyperpolarized molecule of interest dissolved therein at a third concentration.

Embodiment 12. The method of Embodiment 11, wherein (c) comprises performing the MRI or NMR procedure using the aqueous solution.

Embodiment 13. The method of Embodiment 11 or 12, wherein the third concentration is at least 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, or more.

Embodiment 14. A composition for use in a magnetic resonance imaging (MRI) or nuclear magnetic resonance (NMR) procedure, the composition comprising:
a solution and a hyperpolarized molecule of interest dissolved therein, wherein the composition is generated by:
   (a) obtaining an organic solution having the hyperpolarized molecule of interest dissolved therein at a first concentration; and
   (b) evaporating at least a portion of the organic solution to thereby generate an organic solution having the hyperpolarized molecule of interest dissolved therein at a second concentration greater than the first concentration.

Embodiment 15. The composition of Embodiment 14, wherein the first concentration is less than 100 millimolar (mM), 90 mM, 80 mM, 70 mM, 60 mM, 50 mM, 40 mM, 30 mM, 20 mM, 10 mM, or less.

Embodiment 16. The composition of Embodiment 14 or 15, wherein the second concentration is at least 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, or more.

Embodiment 17. The composition of any one of Embodiments 14-16, wherein the organic solution comprises at least one organic molecule selected from the group consisting of: methanol, ethanol, n-propanol, isopropanol, and acetone.

Embodiment 18. The composition of any one of Embodiments 14-17, wherein (b) comprises evaporating at least the portion by performing at least one evaporation procedure selected from the group consisting of: flowing an inert gas across the organic solution, subjecting the organic solution to vacuum, and heating the organic solution.

Embodiment 19. The composition of any one of Embodiments 14-18, wherein (a)-(b) are conducted for a total period of at most 150 seconds(s), 140 s, 130 s, 120 s, 110 s, 100 s, 90 s, 80 s, 70 s, 60 s, 50 s, 40 s, 30 s, 20 s, 19 s, 18 s, 17 s, 16 s, 15 s, 14 s, 13 s, 12 s, 11 s, 10 s, 9 s, 8 s, 7 s, 6 s, 5 s, 4 s, 3 s, 2 s, 1 s, or less.

Embodiment 20. The composition of any one of Embodiments 14-19, wherein immediately following (a), the hyperpolarized molecule of interest has a first nuclear spin polarization, wherein immediately prior to use of the composition in the MRI or NMR procedure, the hyperpolarized molecule of interest has a second nuclear spin polarization, and wherein the second nuclear spin polarization is reduced from the first nuclear spin polarization by no more than 10%, 20%, 30%, 40%, or 50%.

Embodiment 21. The composition of any one of Embodiments 14-20, wherein the composition is further generated by: prior to (a), generating the hyperpolarized molecule of interest using at least one hyperpolarization procedure selected from the group consisting of: parahydrogen induced polarization (PHIP), PHIP-sidearm hydrogenation (PHIP-SAH), PHIP nuclear Overhauser effect system (PHIPNOESYS), and signal amplification by reversible exchange (SABRE).

Embodiment 22. The composition of any one of Embodiments 14-21, wherein the hyperpolarized molecule of interest is selected from the group consisting of: dimethyl maleate, pyruvate, glutamate, glutamine, lactate, acetate, acetoacetate, zymonate, alanine, fructose, fumarate, bicarbonate, urea, dehydroascorbate, alpha-ketoglutarate, dihydroxyacetone, glucose, ascorbate, and conjugate acids thereof.

Embodiment 23. The composition of any one of Embodiments 14-22, wherein the MRI or NMR procedure is performed using the organic solution.

Embodiment 24. The composition of any one of Embodiments 14-22, wherein the composition is further generated by: subsequent to (b), mixing the organic solution with water to thereby generate an aqueous solution having the hyperpolarized molecule of interest dissolved therein at a third concentration.

Embodiment 25. The composition of Embodiment 24, wherein the MRI or NMR procedure is performed using the aqueous solution.

Embodiment 26. The composition of Embodiment 24 or 25, wherein the third concentration is at least 50 mM, 60 mM, 70 mM, 80 mM, 90 mM, 100 mM, 110 mM, 120 mM, 130 mM, 140 mM, 150 mM, 160 mM, 170 mM, 180 mM, 190 mM, 200 mM, or more.

Embodiment 27. A method for increasing a nuclear spin polarization in a molecule of interest, comprising:
(a) obtaining a molecule of interest comprising at least one deuterium atom;
(b) locating the molecule of interest in a magnetic field having a mean magnetic field strength (B₀) of at most about 2 Tesla (T);
(c) forming a coordination complex between the molecule of interest, a signal amplification by reversible exchange (SABRE) catalyst or pre-catalyst, and parahydrogen; and
(d) applying an oscillating magnetic field to the coordination complex to thereby transfer spin order from the parahydrogen to the molecule of interest and to thereby increase the nuclear spin polarization of at least one atom in the molecule of interest.

Embodiment 28. The method of Embodiment 27, wherein the molecule of interest comprises a deuterated chemical analog of a biorelevant imaging agent.

Embodiment 29. The method of Embodiment 28, wherein the biorelevant imaging agent is selected from: pyruvate, alpha-ketoglutarate, Z-4-methyl-2-oxopent-3-enedioc acid (Z-OMPD), zymonate, urea, azidothymidine (AZT), metronidazole, trimethylphenylammonium (TMPA), pyridine, nicotinamide, a diazirine tag, and conjugate acids thereof.

Embodiment 30. The method of any one of Embodiments 27-29, wherein the molecule of interest comprises at least one carbon-13 (¹³C) atom or nitrogen-15 (¹⁵N) atom.

Embodiment 31. The method of any one of Embodiments 27-30, wherein the molecule of interest comprises at least two deuterium atoms or at least three deuterium atoms.

Embodiment 32. The method of any one of Embodiments 27-31, wherein the mean magnetic field strength is at least about 1 μT, 2 μT, 3 μT, 4μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 millitesla (mT), 2 mT, 3 mT, 4 mT, 5 mT, 6 mT, 7 mT, 8 mT, 9 mT, 10 mT, 20 mT, 30 mT, 40 mT, 50 mT, 60 mT, 70 mT, 80 mT, 90 mT, 100 mT, 300 mT, 400 mT, 500 mT, 600 mT, 700 mT, 800 mT, 900 mT, 1 T, or more.

Embodiment 33. The method of any one of Embodiments 27-32, wherein the mean magnetic field strength is at most about 1 T, 900 mT, 800 mT, 700 mT, 600 mT, 500 mT, 400 mT, 300 mT, 200 mT, 100 mT, 90 mT, 80 mT, 70 mT, 60 mT, 50 mT, 40 mT, 30 mT, 20 mT, 10 mT, 9 mT, 8 mT, 7 mT, 6 mT, 5 mT, 4 mT, 3 mT, 2 mT, 1 mT, 900 μT, 800 μT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, or less.

Embodiment 34. The method of any one of Embodiments 27-33, wherein the SABRE catalyst or pre-catalyst comprises an iridium (Ir) complex or a cobalt (Co) complex.

Embodiment 35. The method of Embodiment 34, wherein the SABRE catalyst or pre-catalyst comprises [IrCI(COD)(IMes)].

Embodiment 36. The method of any one of Embodiments 27-35, wherein the oscillating magnetic field has a maximum field strength of at most about 10 mT.

Embodiment 37. The method of Embodiment 36, wherein the oscillating magnetic field has a maximum field strength of at least about 0.1 μT, 0.2 μT, 0.3 μT, 0.4 μT, 0.5 μT, 0.6 μT, 0.7 μT, 0.8 μT, 0.9 μT, 1 μT, 2 μT, 3 μT, 4 μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 mT, 2 mT, 3 mT, 4 mT, 5 mT, 6 mT, 7 mT, 8 mT, 9 mT, 10 mT, or more.

Embodiment 38. The method of Embodiment 36 or 37, wherein the oscillating magnetic field has a maximum field strength of at most about 10 mT, 9 mT, 8 mT, 7 mT, 6 mT, 5 mT, 4 mT, 3 mT, 2 mT, 1 mT, 900 μT, 800 μT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, 0.9 μT, 0.8 μT, 0.7 μT, 0.6 μT, 0.5 μT, 0.4 μT, 0.3 μT, 0.2 μT, 0.1 μT, or less.

Embodiment 39. The method of any one of Embodiments 27-38, further comprising performing (a)-(d) in a magnetic shield.

Embodiment 40. The method of Embodiment 39, wherein the magnetic shield comprises a mu metal magnetic shield.

Embodiment 41. The method of any one of Embodiments 27-40, wherein (c) is performed in a solution comprising the molecule of interest, the SABRE catalyst or pre-catalyst, and the parahydrogen.

Embodiment 42. The method of Embodiment 41, further comprising bubbling the parahydrogen into the solution.

Embodiment 43. The method of Embodiment 42, wherein the parahydrogen is bubbled into the solution at a pressure of at between 1 bar and 50 bar.

Embodiment 44. The method of any one of Embodiments 27-43, wherein, subsequent to (d), the nuclear spin polarization in the molecule of interest is at least about 1%, 2%, 3%, 4%, 5%, 6%, 7%, 8%, 9%, 10%, 11%, 12%, 13%, 14%, 15%, 16%, 17%, 18%, 19%, 20%, or more.

Embodiment 45. The method of any one of Embodiments 27-44, wherein the mean magnetic field strength is between about 1 μT and about 50 mT.

Embodiment 46. A composition for use in a magnetic resonance imaging (MRI) or nuclear magnetic resonance (NMR) procedure, the composition comprising:
a solution and a hyperpolarized molecule of interest dissolved therein, wherein the composition is generated by:
   (a) obtaining a molecule of interest comprising at least one deuterium atom;
   (b) locating the molecule of interest in a magnetic field having a mean magnetic field strength (B₀) of at most about 2 Tesla (T);
   (c) forming a coordination complex between the molecule of interest, a signal amplification by reversible exchange (SABRE) catalyst or pre-catalyst, and parahydrogen; and
   (d) applying an oscillating magnetic field to the coordination complex to thereby transfer spin order from the parahydrogen to the molecule of interest and to thereby increase the nuclear spin polarization of at least one atom in the molecule of interest.

Embodiment 47. The composition of Embodiment 46, wherein the molecule of interest comprises a deuterated chemical analog of a biorelevant imaging agent.

Embodiment 48. The composition of Embodiment 47, wherein the biorelevant imaging agent is selected from: pyruvate, alpha-ketoglutarate, Z-4-methyl-2-oxopent-3-enedioc acid (Z-OMPD), zymonate, urea, azidothymidine (AZT), metronidazole, trimethylphenylammonium (TMPA), pyridine, nicotinamide, a diazirine tag, and conjugate acids thereof.

Embodiment 49. The composition of any one of Embodiments 46-48, wherein the molecule of interest comprises at least one carbon-13 (¹³C) atom or nitrogen-15 (¹⁵N) atom.

Embodiment 50. The composition of any one of Embodiments 46-49, wherein the molecule of interest comprises at least two deuterium atoms or at least three deuterium atoms.

Embodiment 51. The composition of any one of Embodiments 46-50, wherein the mean magnetic field strength is at least about 1 μT, 2 μT, 3 μT, 4 μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 millitesla (mT), 2 mT, 3 mT, 4 mT, 5 mT, 6 mT, 7 mT, 8 mT, 9 mT, 10 mT, 20 mT, 30 mT, 40 mT, 50 mT, 60 mT, 70 mT, 80 mT, 90 mT, 100 mT, 300 mT, 400 mT, 500 mT, 600 mT, 700 mT, 800 mT, 900 mT, 1 T, or more.

Embodiment 52. The composition of any one of Embodiments 46-51, wherein the mean magnetic field strength is at most about 1 T, 900 mT, 800 mT, 700 mT, 600 mT, 500 mT, 400 mT, 300 mT, 200 mT, 100 mT, 90 mT, 80 mT, 70 mT, 60 mT, 50 mT, 40 mT, 30 mT, 20 mT, 10 mT, 9 mT, 8 mT, 7 mT, 6 mT, 5 mT, 4 mT, 3 mT, 2 mT, 1 mT, 900 μT, 800 μT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, or less.

Embodiment 53. The composition of any one of Embodiments 46-52, wherein the SABRE catalyst or pre-catalyst comprises an iridium (Ir) complex or a cobalt (Co) complex.

Embodiment 54. The composition of Embodiment 53, wherein the SABRE catalyst or pre-catalyst comprises [IrCI(COD)(IMes)].

Embodiment 55. The composition of any one of Embodiments 46-54, wherein the oscillating magnetic field has a maximum field strength of at most about 10 mT.

Embodiment 56. The composition of Embodiment 55, wherein the oscillating magnetic field has a maximum field strength of at least about 0.1 μT, 0.2 μT, 0.3 μT, 0.4 μT, 0.5 μT, 0.6 μT, 0.7 μT, 0.8 μT, 0.9 μT, 1 μT, 2 μT, 3 μT, 4 μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 30 0μT, 400 μT, 500 μT, 600 μT, 700 μT, 800 μT, 900 μT, 1 mT, 2 mT, 3 mT, 4 mT, 5 mT, 6 mT, 7 mT, 8 mT, 9 mT, 10 mT, or more.

Embodiment 57. The composition of Embodiment 55 or 56, wherein the oscillating magnetic field has a maximum field strength of at most about 10 mT, 9 mT, 8 mT, 7 mT, 6 mT, 5 mT, 4 mT, 3 mT, 2 mT, 1 mT, 900 μT, 800 μT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, 0.9 μT, 0.8 μT, 0.7 μT, 0.6 μT, 0.5 μT, 0.4 μT, 0.3 μT, 0.2 μT, 0.1 μT, or less.

Embodiment 58. The composition of any one of Embodiments 46-57, wherein the composition is generated by performing (a)-(d) in a magnetic shield.

Embodiment 59. The composition of Embodiment 58, wherein the magnetic shield comprises a mu metal magnetic shield.

Embodiment 60. The composition of any one of Embodiments 46-59, wherein (c) is performed in a solution comprising the molecule of interest, the SABRE catalyst or pre-catalyst, and the parahydrogen.

Embodiment 61. The composition of Embodiment 60, wherein the composition is generated by bubbling the parahydrogen into the solution.

Embodiment 62. The composition of Embodiment 61, wherein the parahydrogen is bubbled into the solution at a pressure of at between 1 bar and 50 bar.

Embodiment 63. The composition of any one of Embodiments 46-62, wherein, subsequent to (d), the nuclear spin polarization in the molecule of interest is at least about 1%, 2%, 3%, 4%, 5%, 6%, 7%, 8%, 9%, 10%, 11%, 12%, 13%, 14%, 15%, 16%, 17%, 18%, 19%, 20%, or more.

Embodiment 64. The composition of any one of Embodiments 46-63, wherein the mean magnetic field strength is between about 1 μT and about 50 mT.

1. A method for increasing a nuclear spin polarization in a molecule of interest, comprising:
(a) obtaining a molecule of interest comprising at least one deuterium atom;
(b) locating the molecule of interest in a magnetic field having a mean magnetic field strength (B₀) of at most about 2 Tesla (T);
(c) forming a coordination complex between the molecule of interest, a signal amplification by reversible exchange (SABRE) catalyst or pre-catalyst, and parahydrogen; and
(d) applying an oscillating magnetic field to the coordination complex to thereby transfer spin order from the parahydrogen to the molecule of interest and to thereby increase the nuclear spin polarization of at least one atom in the molecule of interest.

2. The method of claim 1, wherein the molecule of interest comprises a deuterated chemical analog of a biorelevant imaging agent.

3. The method of claim 2, wherein the biorelevant imaging agent is selected from:
pyruvate, alpha-ketoglutarate, Z-4-methyl-2-oxopent-3-enedioc acid (Z-OMPD), zymonate, urea, azidothymidine (AZT), metronidazole, trimethylphenylammonium (TMPA), pyridine, nicotinamide, a diazirine tag, and conjugate acids thereof.

4. The method of any one of claims 1-3, wherein the molecule of interest comprises at least one carbon-13 (¹³C) atom or nitrogen-15 (¹⁵N) atom.

5. The method of any one of claims 1-4, wherein the molecule of interest comprises at least two deuterium atoms or at least three deuterium atoms.

6. The method of any one of claims 1-5, wherein the mean magnetic field strength is at least about 1 μT, 2 μT, 3 μT, 4 μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 millitesla (mT), 2 mT, 3 mT, 4 mT, 5 mT, 6 mT, 7 mT, 8 mT, 9 mT, 10 mT, 20 mT, 30 mT, 40 mT, 50 mT, 60 mT, 70 mT, 80 mT, 90 mT, 100 mT, 300 mT, 400 mT, 500 mT, 600 mT, 700 mT, 800 mT, 900 mT, 1 T, or more.

7. The method of any one of claims 1-6, wherein the mean magnetic field strength is at most about 1 T, 900 mT, 800 mT, 700 mT, 600 mT, 500 mT, 400 mT, 300 mT, 200 mT, 100 mT, 90 mT, 80 mT, 70 mT, 60 mT, 50 mT, 40 mT, 30 mT, 20 mT, 10 mT, 9 mT, 8 mT, 7 mT, 6 mT, 5 mT, 4 mT, 3 mT, 2 mT, 1 mT, 900 μT, 800 UT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, or less.

8. The method of any one of claims 1-7, wherein the SABRE catalyst or pre-catalyst comprises an iridium (Ir) or a cobalt (Co) complex.

9. The method of claim 8, wherein the SABRE catalyst or pre-catalyst comprises [IrCl(COD)(IMes)].

10. The method of any one of claims 1-9, wherein the oscillating magnetic field has a maximum field strength of at most about 10 mT.

11. The method of claim 10, wherein the oscillating magnetic field has a maximum field strength of at least about 0.1 μT, 0.2 μT, 0.3 μT, 0.4 μT, 0.5 μT, 0.6 μT, 0.7 μT, 0.8 μT, 0.9 μT, 1 μT, 2 μT, 3 μT, 4 μT, 5 μT, 6 μT, 7 μT, 8 μT, 9 μT, 10 μT, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 mT, 2 mT, 3 mT, 4 mT, 5 mT, 6 mT, 7 mT, 8 mT, 9 mT, 10 mT, or more.

12. The method of claim 10 or 11, wherein the oscillating magnetic field has a maximum field strength of at most about 10 mT, 9 mT, 8 mT, 7 mT, 6 mT, 5 mT, 4 mT, 3 mT, 2 mT, 1 mT, 900 μT, 800 μT, 700 μT, 600 μT, 500 μT, 400 μT, 300μT, 200 μT, 100 μT, 90 μT, 80 μT, 70 μT, 60 μT, 50 μT, 40 μT, 30 μT, 20 μT, 10 μT, 9 μT, 8 μT, 7 μT, 6 μT, 5 μT, 4 μT, 3 μT, 2 μT, 1 μT, 0.9 μT, 0.8 μT, 0.7 μT, 0.6 μT, 0.5 μT, 0.4 μT, 0.3 μT, 0.2 μT, 0.1 μT, or less.

13. The method of any one of claims 1-12, further comprising performing (a)-(d) in a magnetic shield.

14. The method of claim 13, wherein the magnetic shield comprises a mu metal magnetic shield.

15. The method of any one of claims 1-14, wherein (c) is performed in a solution comprising the molecule of interest, the SABRE catalyst or pre-catalyst, and the parahydrogen.

16. The method of claim 15, further comprising bubbling the parahydrogen into the solution.

17. The method of claim 16, wherein the parahydrogen is bubbled into the solution at a pressure of at between 1 bar and 50 bar.

18. The method of any one of claims 1-17, wherein, subsequent to (d), the nuclear spin polarization in the molecule of interest is at least about 1%, 2%, 3%, 4%, 5%, 6%, 7%, 8%, 9%, 10%, 11%, 12%, 13%, 14%, 15%, 16%, 17%, 18%, 19%, 20%, or more.

19. The method of any one of claims 1-18, wherein the mean magnetic field strength is between about 1 μT and about 50 mT.
